(19) United States
(12) Patent Application Publication
(10) Pub. No.: US 2024/0055482 A1
(43) Pub. Date: Feb. 15, 2024

(54) SEMICONDUCTOR DEVICE

(71) Applicant: SAMSUNG ELECTRONICS CO., LTD., SUWON-SI (KR)

(72) Inventors: Seok Hyeon YOON, Suwon-si (KR); Kyo-Wook LEE, Suwon-si (KR); Seung Hun LEE, Suwon-si (KR); Seung Han PARK, Suwon-si (KR)

(21) Appl. No.: 18/193,758

(22) Filed: Mar. 31, 2023

(30) Foreign Application Priority Data
Aug. 12, 2022 (KR) 10-2022-0101150

(51) Int. Cl. H01L 29/06; H01L 27/092; H01L 29/786; H01L 23/48; H01L 29/66; H01L 29/775; H01L 29/423; H01L 29/417

(52) U.S. Cl. CPC H01L 29/0673; H01L 27/092; H01L 29/78696; H01L 23/481; H01L 29/66545; H01L 29/775; H01L 29/42392; H01L 29/41733

(57) ABSTRACT

A semiconductor device including: first and second cell regions; a substrate including first and second surfaces; first to third active patterns extending in a first horizontal direction in the first cell region, the first to third active patterns spaced apart from each other in a second horizontal direction; a fourth active pattern extending in the first horizontal direction in the second cell region, the fourth active pattern is aligned with the second active pattern in the first horizontal direction; an active cut separating the second and fourth active patterns; a source/drain region on the second active pattern; a buried rail extending in the first horizontal direction on the second surface of the substrate, the first buried rail overlaps each of the second and fourth active patterns in a vertical direction; and a source/drain contact penetrating the substrate and second active pattern and connecting the source/drain region to the buried rail.

### CROSS-REFERENCE TO RELATED APPLICATION

This application claims priority under 35 U.S.C. § 119 to Korean Patent Application No. 10-2022-0101150 filed on Aug. 12, 2022 in the Korean Intellectual Property Office, the disclosure of which is incorporated by reference herein in its entirety.

### 1. TECHNICAL FIELD

The present disclosure relates to a semiconductor device. More particularly, the present disclosure relates to a semiconductor device including a multi-bridge channel field effect transistor (MBCFET™).

### 2. DESCRIPTION OF THE RELATED ART

An integrated circuit is a set of electronic circuits on a small flat piece of semiconductor material, usually silicon. The integrated circuit may be designed based on standard cells. For example, the layout of the integrated circuit may be generated by arranging standard cells according to data defining the integrated circuit and routing the standard cells. A standard cell is predesigned and stored in a cell library.

As a semiconductor manufacturing process produces integrated circuits with a higher level of integration, the size of patterns in the standard cell may decrease, and the size of the standard cell may also decrease.

### SUMMARY

Embodiments of the present disclosure provide a semiconductor device having an increased degree of integration by forming two pull-up transistors on one active pattern in one cell region to reduce the number of active patterns in one cell region.

Embodiments of the present disclosure also provide a semiconductor device having an increased degree of integration by disposing an active cut between two pull-up transistors in a first cell region and two pull-up transistors in a second cell region adjacent to the first cell region and arranging the two pull-up transistors in the first cell region and the two pull-up transistors in the second cell region to be aligned in a horizontal direction.

Embodiments of the present disclosure also provide a semiconductor device having an increased degree of integration by disposing an active cut between two pull-down transistors in a first cell region and two pull-down transistors in a second cell region adjacent to the first cell region and arranging the two pull-down transistors in the first cell region and the two pull-down transistors in the second cell region to be aligned in the horizontal direction.

According to some embodiments of the present disclosure, there is provided a semiconductor device including: a first cell region and a second cell region adjacent to the first cell region in a first horizontal direction; a substrate including a first surface and a second surface opposite to the first surface; first, second and third active patterns extending in the first horizontal direction on the first surface of the substrate in the first cell region, the first, second and third active patterns are sequentially spaced apart from each other in a second horizontal direction different from the first horizontal direction; a fourth active pattern extending in the first horizontal direction on the first surface of the substrate in the second cell region, the fourth active pattern is aligned with the second active pattern in the first horizontal direction; a first active cut separating the second active pattern and the fourth active pattern, the first active cut is in contact with each of the second active pattern and the fourth active pattern; a first source/drain region disposed on the second active pattern; a first buried rail extending in the first horizontal direction on the second surface of the substrate, the first buried rail overlaps each of the second and fourth active patterns in a vertical direction; and a first lower source/drain contact penetrating the substrate and the second active pattern in the vertical direction, the first lower source/drain contact electrically connects the first source/drain region to the first buried rail.

According to some embodiments of the present disclosure, there is provided a semiconductor device including: a first cell region and a second cell region adjacent to the first cell region in a first horizontal direction; a substrate including a first surface and a second surface opposite to the first surface; first, second and third active patterns extending in the first horizontal direction on the first surface of the substrate in the first cell region, the first, second and third active patterns are sequentially spaced apart from each other in a second horizontal direction different from the first horizontal direction; a fourth active pattern extending in the first horizontal direction on the first surface of the substrate in the second cell region, the fourth active pattern is aligned with the second active pattern in the first horizontal direction; an active cut separating the second active pattern from the fourth active pattern, the active cut is in contact with each of the second active pattern and the fourth active pattern; a first source/drain region disposed on the first active pattern; a second source/drain region disposed on the second active pattern; a third source/drain region disposed on the third active pattern; a first buried rail extending in the first horizontal direction on the second surface of the substrate, the first buried rail overlaps the first active pattern in a vertical direction; a second buried rail extending in the first horizontal direction on the second surface of the substrate, the second buried rail overlaps the second and fourth active patterns in the vertical direction; a third buried rail extending in the first horizontal direction on the second surface of the substrate, the third buried rail overlaps the third active pattern in the vertical direction; a first lower source/drain contact penetrating the substrate and the first active pattern in the vertical direction, the first lower source/drain contact electrically connects the first source/drain region to the first buried rail; a second lower source/drain contact penetrating the substrate and the second active pattern in the vertical direction, the second lower source/drain contact electrically connects the second source/drain region to the second buried rail; and a third lower source/drain contact penetrating the substrate and the third active pattern in the vertical direction, the third lower source/drain contact electrically connects the third source/drain region to the third buried rail.

According to some embodiments of the present disclosure, there is provided a semiconductor device including: a first cell region and a second cell region adjacent to the first cell region in a first horizontal direction; a substrate including a first surface and a second surface opposite to the first surface; first, second and third active patterns extending in the first horizontal direction on the first surface of the substrate in the first cell region, the first, second and third active patterns are sequentially spaced apart from each other in a second horizontal direction different from the first horizontal direction; a fourth active pattern extending in the first horizontal direction on the first surface of the substrate in the second cell region, the fourth active pattern is aligned with the second active pattern in the first horizontal direction; a first gate electrode extending in the second horizontal direction on the second active pattern; a second gate electrode extending in the second horizontal direction on the second active pattern, the second gate electrode is spaced apart from the first gate electrode in the first horizontal direction; a third gate electrode extending in the second horizontal direction on the fourth active pattern, the third gate electrode is spaced apart from the second gate electrode in the first horizontal direction; a fourth gate electrode extending in the second horizontal direction on the fourth active pattern, the fourth gate electrode is spaced apart from the third gate electrode in the first horizontal direction; a first pull-up transistor formed where the second active pattern and the first gate electrode intersect; a second pull-up transistor formed where the second active pattern and the second gate electrode intersect; a third pull-up transistor formed where the fourth active pattern and the third gate electrode intersect; and a fourth pull-up transistor formed where the fourth active pattern and the fourth gate electrode intersect, wherein each of the first to fourth pull-up transistors is aligned in the first horizontal direction.

### BRIEF DESCRIPTION OF THE DRAWINGS

The above and other features of the present disclosure will become more apparent by describing in detail embodiments thereof with reference to the attached drawings, in which:

FIG. 1 is a layout diagram illustrating a semiconductor device according to some embodiments of the present disclosure;

FIG. 2 is a layout diagram illustrating an arrangement of a plurality of transistors in FIG. 1;

FIG. 3 is a layout diagram illustrating a connection relationship between buried rails in FIG. 1;

FIG. 4 is a layout diagram illustrating a connection relationship between a gate contact and an upper source/drain contact in FIG. 1;

FIG. 5 is a cross-sectional view taken along line A-A′ in each of FIGS. 1 to 4;

FIG. 6 is a cross-sectional view taken along line B-B′ in each of FIGS. 1 to 4;

FIG. 7 is a cross-sectional view taken along line C-C′ in each of FIGS. 1 to 4;

FIGS. 8, 9 and 10 are cross-sectional views illustrating a semiconductor device according to some other embodiments of the present disclosure;

FIGS. 11 and 12 are layout diagrams illustrating a semiconductor device according to some other embodiments of the present disclosure;

FIG. 13 is a layout diagram illustrating a semiconductor device according to still other embodiments of the present disclosure;

FIG. 14 is a layout diagram illustrating an arrangement of a plurality of transistors in FIG. 13;

FIG. 15 is a layout diagram illustrating a connection relationship between buried rails in FIG. 13.

FIG. 16 is a layout diagram illustrating a connection relationship between a gate contact and an upper source/drain contact in FIG. 13;

FIG. 17 is a cross-sectional view taken along line D-D′ in each of FIGS. 13 to 16;

FIGS. 18 and 19 are layout views illustrating a semiconductor device according to some other embodiments of the present disclosure;

FIG. 20 is a layout diagram illustrating a semiconductor device according to still other embodiments of the present disclosure;

FIG. 21 is a layout diagram illustrating an arrangement of a plurality of transistors in FIG. 20;

FIG. 22 is a layout diagram illustrating a connection relationship between buried rails in FIG. 20;

FIG. 23 is a layout diagram illustrating a connection relationship between a gate contact and an upper source/drain contact in FIG. 20;

FIG. 24 is a cross-sectional view taken along line E-E′ in each of FIGS. 20 to 23;

FIG. 25 is a cross-sectional view taken along line F-F′ in each of FIGS. 20 to 23; and

FIGS. 26 and 27 are layout diagrams illustrating a semiconductor device according to some other embodiments of the present disclosure.

### DETAILED DESCRIPTION OF THE EMBODIMENTS

Although the drawings of the semiconductor device according to some embodiments of the present disclosure illustrate, for example, a multi-bridge channel field effect transistor (MBCFET™) including a nanosheet and a fin-type transistor (FinFET) including a fin-type pattern-shaped channel region, the present disclosure is not limited thereto. For example, the semiconductor device according to some other embodiments of the present disclosure may include a tunneling field effect transistor (TFET) or a three-dimensional (3D) transistor. Further, the semiconductor device according to some other embodiments of the present disclosure may include a bipolar junction transistor, a lateral double diffusion MOS (LDMOS) transistor, or the like.

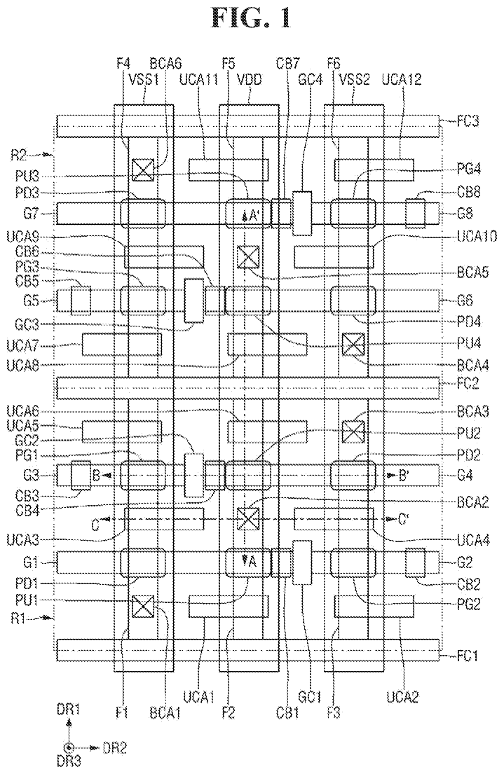

Hereinafter, a semiconductor device according to some embodiments of the present disclosure will be described with reference to FIGS. 1 to 7.

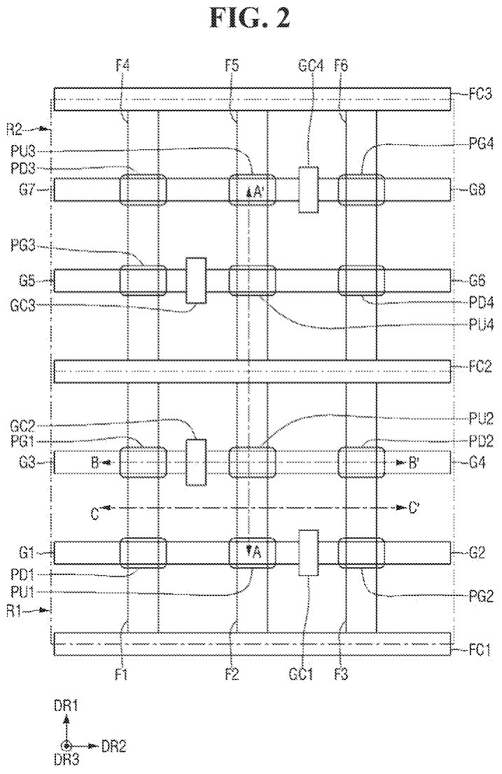

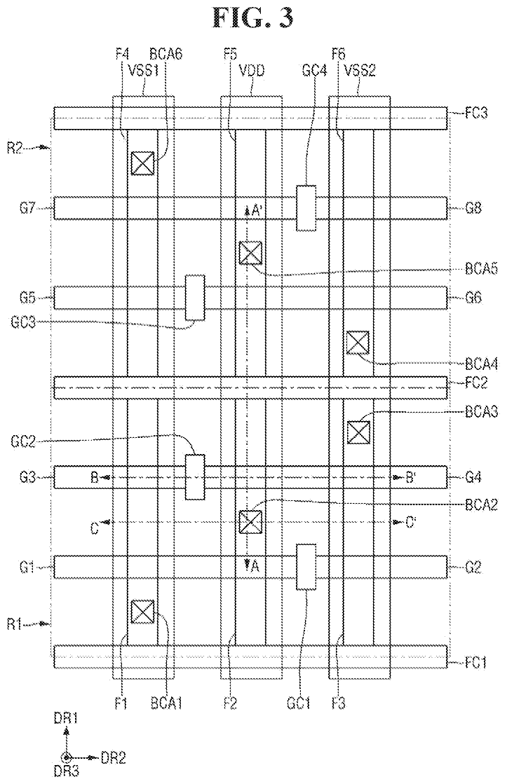

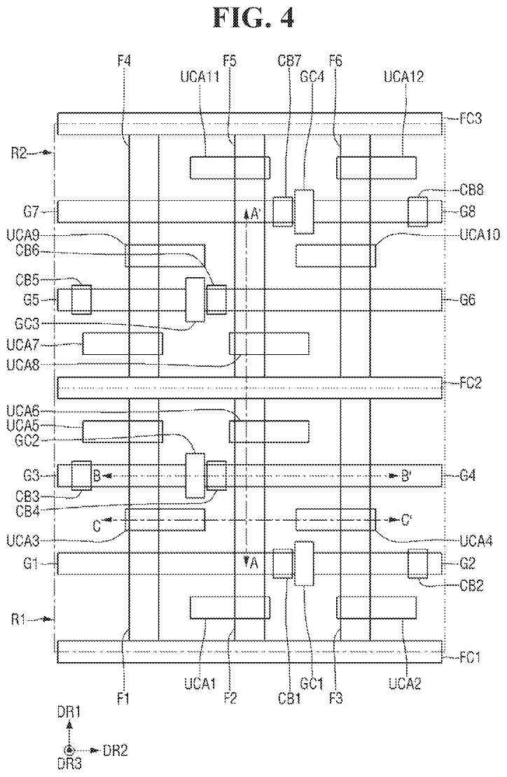

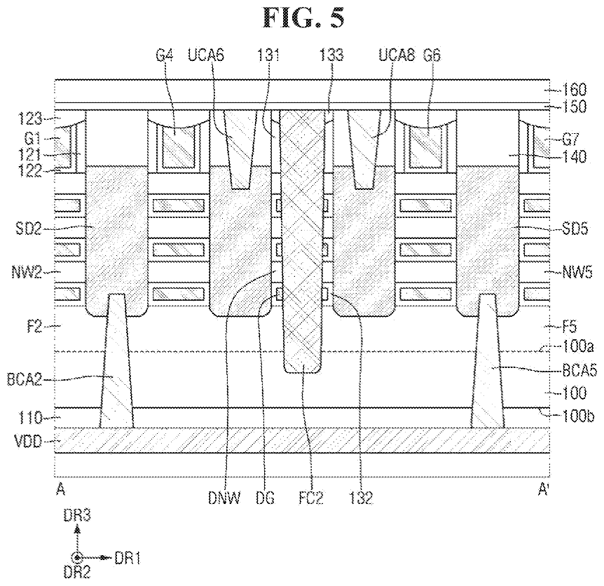

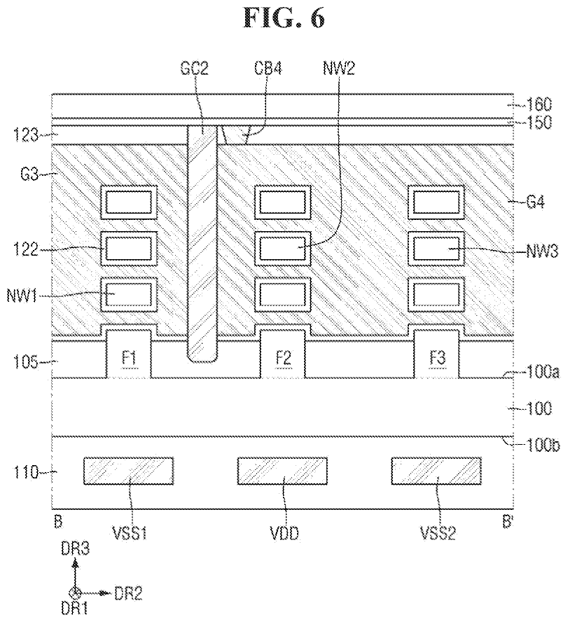

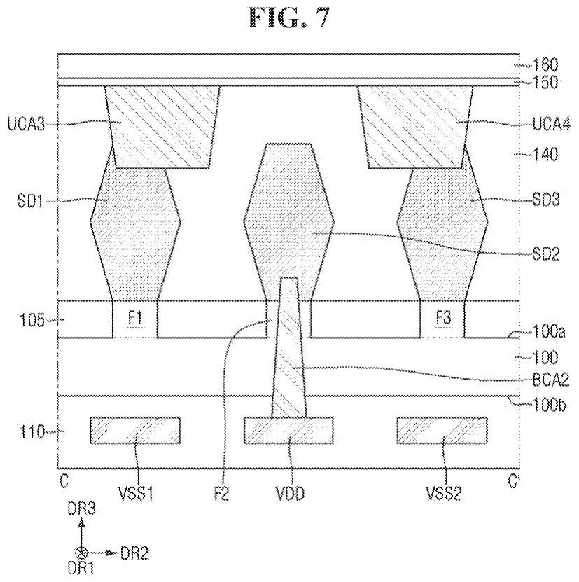

FIG. 1 is a layout diagram illustrating a semiconductor device according to some embodiments of the present disclosure. FIG. 2 is a layout diagram illustrating an arrangement of a plurality of transistors in FIG. 1. FIG. 3 is a layout diagram illustrating a connection relationship between buried rails in FIG. 1. FIG. 4 is a layout diagram illustrating a connection relationship between a gate contact and an upper source/drain contact in FIG. 1. FIG. 5 is a cross-sectional view taken along line A-A′ in each of FIGS. 1 to 4. FIG. 6 is a cross-sectional view taken along line B-B′ in each of FIGS. 1 to 4. FIG. 7 is a cross-sectional view taken along line C-C′ in each of FIGS. 1 to 4.

Referring to FIGS. 1 to 7, a semiconductor device according to some embodiments of the present disclosure includes a first cell region R1, a second cell region R2, a substrate 100, a field insulating layer 105, first, second, third, fourth, fifth and sixth active patterns F1, F2, F3, F4, F5 and F6, a first buried rail VSS1, a second buried rail VDD, a third buried rail VSS2, a lower interlayer insulating layer 110, first to sixth pluralities of nanosheets, first, second, third, fourth, fifth, sixth, seventh and eighth gate electrodes G1, G2, G3, G4, G5, G6, G7 and G8, a gate spacer 121, a gate insulating layer 122, a capping pattern 123, first to sixth source/drain regions, first, second, third and fourth gate cuts GC1, GC2, GC3 and GC4, first, second and third active cuts FC1, FC2, and FC3, a dummy gate electrode DG, a dummy gate spacer 131, a dummy gate insulating layer 132, a dummy capping pattern 133, a plurality of dummy nanosheets DNW, first, second, third and fourth pull-down transistors PD1, PD2, PD3 and PD4, first, second, third and fourth pull-up transistors PU1, PU2, PU3 and PU4, first, second, third and fourth pass transistors PG1, PG2, PG3 and PG4, a first upper interlayer insulating layer 140, first, second, third, fourth, fifth, sixth, seventh and eighth gate contacts CB1, CB2, CB3, CB4, CB5, CB6, CB7 and CB8, first, second, third, fourth, fifth, sixth, seventh, eighth, ninth, tenth, eleventh and twelfth upper source/drain contacts UCA1, UCA2, UCA3, UCA4, UCA5, UCA6, UCA7, UCA8, UCA9, UCA10, UCA11 and UCA12, first, second, third, fourth, fifth and sixth lower source/drain contacts BCA1, BCA2, BCA3, BCA4, BCA5 and BCA6, an etch stop layer 150, and a second upper interlayer insulating layer 160.

Hereinafter, each of a first horizontal direction DR1 and a second horizontal direction DR2 is a direction parallel to a first surface 100a that is the top surface of the substrate 100, and the second horizontal direction DR2 is a direction perpendicular to the first horizontal direction DRL. Further, a vertical direction DR3 is a direction perpendicular to each of the first and second horizontal directions DR1 and DR2, and is a direction perpendicular to the first surface 100a of the substrate 100.

The second cell region R2 may be formed to be directly adjacent to the first cell region R1 in the first horizontal direction DR1. The first cell region R1 and the second cell region R2 may be storage regions. In other words, a storage device may be formed in each of the first cell region R1 and the second cell region R2. In this case, the storage device may be a static random access memory (SRAM).

The substrate 100 may include the first surface 100a and a second surface 100b facing the first surface 100a. For example, in FIGS. 5 to 7, the first surface 100a of the substrate 100 may be the top surface of the substrate 100, and the second surface 100b of the substrate 100 may be the bottom surface of the substrate 100.

The substrate 100 may be a bulk silicon or silicon-on-insulator (SOI) substrate. Alternatively, the substrate 100 may be a silicon substrate or may include other materials such as silicon germanium, silicon germanium on insulator (SGOI), indium antimonide, a lead tellurium compound, indium arsenide, indium phosphide, gallium arsenide, or gallium antimonide. However, the present disclosure is not limited thereto.

The first to third active patterns F1, F2, and F3 may be disposed in the first cell region R1. Each of the first to third active patterns F1, F2, and F3 may extend in the first horizontal direction DR1. The first to third active patterns F1, F2, and F3 may be sequentially spaced apart from each other in the second horizontal direction DR2. In other words, the second active pattern F2 may be spaced apart from the first active pattern F1 in the second horizontal direction DR2. Further, the third active pattern F3 may be spaced apart from the second active pattern F2 in the second horizontal direction DR2. More specifically, the second active pattern F2 may be disposed between the first and third active patterns F1 and F3.

The fourth to sixth active patterns F4, F5, and F6 may be disposed in the second cell region R2. Each of the fourth to sixth active patterns F4, F5, and F6 may extend in the first horizontal direction DR1. The fourth to sixth active patterns F4, F5, and F6 may be sequentially spaced apart from each other in the second horizontal direction DR2. In other words, the fifth active pattern F5 may be spaced apart from the fourth active pattern F4 in the second horizontal direction DR2. Further, the sixth active pattern F6 may be spaced apart from the fifth active pattern F5 in the second horizontal direction DR2.

The fourth active pattern F4 may be aligned with the first active pattern F1 in the first horizontal direction DR1. For example the fourth active pattern F4 may face the first active pattern F1. The fourth active pattern F4 may be spaced apart from the first active pattern F1 in the first horizontal direction DR1. The fifth active pattern F5 may be aligned with the second active pattern F2 in the first horizontal direction DR1. The fifth active pattern F5 may be spaced apart from the second active pattern F2 in the first horizontal direction DR1. The sixth active pattern F6 may be aligned with the third active pattern F3 in the first horizontal direction DR1. The sixth active pattern F6 may be spaced apart from the third active pattern F3 in the first horizontal direction DR1. Each of the first to sixth active patterns F1 to F6 may protrude from the first surface 100a of the substrate 100 in the vertical direction DR3.

The field insulating layer 105 may be disposed on the first surface 100a of the substrate 100. The field insulating layer 105 may surround the sidewalls of the first to sixth active patterns F1 to F6. For example, at least a part of each of the first to sixth active patterns F1 to F6 may protrude in the vertical direction DR3 beyond the top surface of the field insulating layer 105, but the present disclosure is not limited thereto. The field insulating layer 105 may include, for example, an oxide layer, a nitride layer, an oxynitride layer, or a combination layer thereof.

The lower interlayer insulating layer 110 may be disposed on the second surface 100b of the substrate 100. The lower interlayer insulating layer 110 may include, for example, at least one of silicon oxide, silicon nitride, silicon oxycarbide, silicon oxynitride, silicon oxycarbonitride, or a low-k material.

Each of the first buried rail VSS1, the second buried rail VDD, and the third buried rail VSS2 may be disposed on the second surface 100b of the substrate 100. Each of the first buried rail VSS1, the second buried rail VDD, and the third buried rail VSS2 may be disposed inside the lower interlayer insulating layer 110. Each of the first buried rail VSS1, the second buried rail VDD, and the third buried rail VSS2 may include a conductive material.

For example, the first buried rail VSS1 may extend in the first horizontal direction DR1 across the first cell region R1 and the second cell region R2. The first buried rail VSS1 may overlap each of the first active pattern F1 and the fourth active pattern F4 in the vertical direction DR3. For example, the first buried rail VSS1 may be a first ground rail.

For example, the second buried rail VDD may extend in the first horizontal direction DR1 across the first cell region R1 and the second cell region R2. The second buried rail VDD may be spaced apart from the first buried rail VSS1 in the second horizontal direction DR2. The second buried rail VDD may overlap each of the second active pattern F2 and the fifth active pattern F5 in the vertical direction DR3. For example, the second buried rail VDD may be a power rail.

For example, the third buried rail VSS2 may extend in the first horizontal direction DR1 across the first cell region R1 and the second cell region R2. The third buried rail VSS2 may be spaced apart from the second buried rail VDD in the second horizontal direction DR2. The third buried rail VSS2 may overlap each of the third active pattern F3 and the sixth active pattern F6 in the vertical direction DR3. For example, the third buried rail VSS2 may be a second ground rail.

Each of the first to fourth gate electrodes G1 to G4 may be disposed in the first cell region R1. For example, the first gate electrode G1 may extend in the second horizontal direction DR2 on the first active pattern F1 and the second active pattern F2. The second gate electrode G2 may extend in the second horizontal direction DR2 on the third active pattern F3. The second gate electrode G2 may be spaced apart from the first gate electrode G1 in the second horizontal direction DR2.

For example, the third gate electrode G3 may extend in the second horizontal direction DR2 on the first active pattern F1. The third gate electrode G3 may be spaced apart from the first gate electrode G1 in the first horizontal direction DR1. The fourth gate electrode G4 may extend in the second horizontal direction DR2 on the second active pattern F2 and the third active pattern F3. The fourth gate electrode G4 may be spaced apart from the third gate electrode G3 in the second horizontal direction DR2. The fourth gate electrode G4 may be spaced apart from each of the first gate electrode G1 and the second gate electrode G2 in the first horizontal direction DR1.

Each of the fifth to eighth gate electrodes G5 to G8 may be disposed in the second cell region R2. For example, the fifth gate electrode G5 may extend in the second horizontal direction DR2 on the fourth active pattern F4. The fifth gate electrode G5 may be spaced apart from the third gate electrode G3 in the first horizontal direction DR1. The sixth gate electrode G6 may extend in the second horizontal direction DR2 on the fifth active pattern F5 and the sixth active pattern F6. The sixth gate electrode G6 may be spaced apart from the fifth gate electrode G5 in the second horizontal direction DR2. The sixth gate electrode G6 may be spaced apart from the fourth gate electrode G4 in the first horizontal direction DR1.

For example, the seventh gate electrode G7 may extend in the second horizontal direction DR2 on the fourth active pattern F4 and the fifth active pattern F5. The seventh gate electrode G7 may be spaced apart from each of the fifth gate electrode G5 and the sixth gate electrode G6 in the first horizontal direction DR1. The eighth gate electrode G8 may extend in the second horizontal direction DR2 on the sixth active pattern F6. The eighth gate electrode G8 may be spaced apart from the seventh gate electrode G7 in the second horizontal direction DR2. The eighth gate electrode G8 may be spaced apart from the sixth gate electrode G6 in the first horizontal direction DR1.

Each of the first to eighth gate electrodes G1 to G8 may include, for example, at least one titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAIN), tungsten nitride (WN), ruthenium (Ru), titanium aluminum (TiAI), titanium aluminum carbonitride (TiAlC—N), titanium aluminum carbide (TiAIC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V) and a combination thereof. Each of the first to eighth gate electrodes G1 to G8 may include a conductive metal oxide, a conductive metal oxynitride or the like, and may include an oxidized form of the aforementioned materials.

A first plurality of nanosheets NW1 may be disposed on the first active pattern F1. The first plurality of nanosheets NW1 may be disposed at the portion where the first active pattern F1 and the first gate electrode G1 intersect. Further, the first plurality of nanosheets NW1 may be disposed at the portion where the first active pattern F1 and the third gate electrode G3 intersect. The first plurality of nanosheets NW1 may include a plurality of nanosheets stacked while being spaced apart from each other in the vertical direction DR3 on the first active pattern F1. The first plurality of nanosheets NW1 may be surrounded by each of the first gate electrode G1 and the third gate electrode G3.

A second plurality of nanosheets NW2 may be disposed on the second active pattern F2. The second plurality of nanosheets NW2 may be disposed at the portion where the second active pattern F2 and the first gate electrode G1 intersect. Further, the second plurality of nanosheets NW2 may be disposed at the portion where the second active pattern F2 and the fourth gate electrode G4 intersect. The second plurality of nanosheets NW2 may include a plurality of nanosheets stacked while being spaced apart from each other in the vertical direction DR3 on the second active pattern F2. The second plurality of nanosheets NW2 may be surrounded by each of the first gate electrode G1 and the fourth gate electrode G4.

A third plurality of nanosheets NW3 may be disposed on the third active pattern F3. The third plurality of nanosheets NW3 may be disposed at the portion where the third active pattern F3 and the second gate electrode G2 intersect. Further, the third plurality of nanosheets NW3 may be disposed at the portion where the third active pattern F3 and the fourth gate electrode G4 intersect. The third plurality of nanosheets NW3 may include a plurality of nanosheets stacked while being spaced apart from each other in the vertical direction DR3 on the third active pattern F3. The third plurality of nanosheets NW3 may be surrounded by each of the second gate electrode G2 and the fourth gate electrode G4.

A fourth plurality of nanosheets may be disposed on the fourth active pattern F4. The fourth plurality of nanosheets may be disposed at the portion where the fourth active pattern F4 and the fifth gate electrode G5 intersect. Further, the fourth plurality of nanosheets may be disposed at the portion where the fourth active pattern F4 and the seventh gate electrode G7 intersect. The fourth plurality of nanosheets may include a plurality of nanosheets stacked while being spaced apart from each other in the vertical direction DR3 on the fourth active pattern F4. The fourth plurality of nanosheets may be surrounded by each of the fifth gate electrode G5 and the seventh gate electrode G7.

A fifth plurality of nanosheets NW5 may be disposed on the fifth active pattern F5. The fifth plurality of nanosheets NW5 may be disposed at the portion where the fifth active pattern F5 and the sixth gate electrode G6 intersect. Further, the fifth plurality of nanosheets NW5 may be disposed at the portion where the fifth active pattern F5 and the seventh gate electrode G7 intersect. The fifth plurality of nanosheets NW5 may include a plurality of nanosheets stacked while being spaced apart from each other in the vertical direction DR3 on the fifth active pattern F5. The fifth plurality of nanosheets NW5 may be surrounded by each of the sixth gate electrode G6 and the seventh gate electrode G7.

A sixth plurality of nanosheets may be disposed on the sixth active pattern F6. The sixth plurality of nanosheets may be disposed at the portion where the sixth active pattern F6 and the sixth gate electrode G6 intersect. Further, the sixth plurality of nanosheets may be disposed at the portion where the sixth active pattern F6 and the eighth gate electrode G8 intersect. The sixth plurality of nanosheets may include a plurality of nanosheets stacked while being spaced apart from each other in the vertical direction DR3 on the sixth active pattern F6. The sixth plurality of nanosheets may be surrounded by each of the sixth gate electrode G6 and the eighth gate electrode G8.

FIGS. 5 to 7 illustrate that each of the first plurality of nanosheets NW1, the second plurality of nanosheets NW2, the third plurality of nanosheets NW3, and the fifth plurality of nanosheets NW5 includes three nanosheets stacked while being spaced apart from each other in the vertical direction DR3, but this is an example and the present disclosure is not limited thereto. In some other embodiments of the present disclosure, each of the first to sixth pluralities of nanosheets may include four or more nanosheets stacked while being spaced apart from each other in the vertical direction DR3. Each of the first to sixth pluralities of nanosheets may include, e.g., silicon (Si) or silicon germanium (SiGe).

The plurality of dummy nanosheets DNW may be disposed on the boundary line of the first cell region R1 extending in the second horizontal direction DR2. Further, the plurality of dummy nanosheets DNW may be disposed on the boundary line of the second cell region R2 extending in the second horizontal direction DR2. For example, the plurality of dummy nanosheets DNW may be disposed on the boundary line between the first cell region R1 and the second cell region R2. The plurality of dummy nanosheets DNW may include a plurality of dummy nanosheets stacked while being spaced apart from each other in the vertical direction DR3. For example, the plurality of dummy nanosheets DNW may be disposed on the same level as the level on which the first to sixth pluralities of nanosheets are disposed.

For example, the plurality of dummy nanosheets DNW may overlap each of a part of the first active pattern F1 adjacent to the second active cut FC2 to be described later and a part of the fourth active pattern F4 in the third direction DR3. Further, the plurality of dummy nanosheets DNW may overlap each of a part of the second active pattern F2 adjacent to the second active cut FC2 to be described later and a part of the fifth active pattern F5 in the vertical direction DR3. Further, the plurality of dummy nanosheets DNW may overlap each of a part of the third active pattern F3 adjacent to the second active cut FC2 to be described later and a part of the sixth active pattern F6 in the vertical direction DR3. The plurality of dummy nanosheets DNW may include, e.g., silicon (Si) or silicon germanium (SiGe).

For example, the dummy gate electrode DG may extend in the second horizontal direction DR2 on both sidewalls of each of the first to third active cuts FC1, FC2, and FC3 to be described later. For example, the dummy gate electrode DG may not be disposed on the uppermost dummy nanosheet among the plurality of dummy nanosheets DNW, but the present disclosure is not limited thereto. The dummy gate electrode DG may contain the same material as that of each of the first to eighth gate electrodes G1 to G8, for example.

The gate spacer 121 may extend in the second horizontal direction DR2 on both sidewalls of each of the first to eighth gate electrodes G1 to G8. The gate spacer 121 may be disposed on both sidewalls of each of the first to eighth gate electrodes G1 to G8 on the uppermost nanosheet of each of the first to sixth pluralities of nanosheets. The gate spacer 121 may be disposed on both sidewalls of each of the first to eighth gate electrodes G1 to G8 on the field insulating layer 105.

The dummy gate spacer 131 may extend in the second horizontal direction DR2 on both sidewalls of each of the first to third active cuts FC1, FC2, and FC3 to be described later on the uppermost dummy nanosheet among the plurality of dummy nanosheets DNW. The dummy gate spacer 131 may extend in the second horizontal direction DR2 on both sidewalls of the dummy gate electrode DG on the field insulating layer 105.

Each of the gate spacer 121 and the dummy gate spacer 131 may include, for example, at least one of silicon nitride (SiN), silicon oxynitride (SiON), silicon carbonitride (SiCN), silicon oxycarbonitride (SiOCN), silicon boron nitride (SiBN), silicon oxyboron nitride (SiOBN), silicon oxycarbide (SiOC), or a combination thereof.

The gate insulating layer 122 may be disposed between each of the first to eighth gate electrodes G1 to G8 and each of the first to sixth pluralities of nanosheets. The gate insulating layer 122 may be disposed between each of the first to eighth gate electrodes G1 to G8 and each of the first to sixth active patterns F1 to F6. The gate insulating layer 122 may be disposed between each of the first to eighth gate electrodes G1 to G8 and the gate spacer 121. The gate insulating layer 122 may be disposed between each of the first to eighth gate electrodes G1 to G8 and the field insulating layer 105. The gate insulating layer 122 may be disposed between each of the first to eighth gate electrodes G1 to G8 and each of the first to sixth source/drain regions to be described later.

The dummy gate insulating layer 132 may be disposed between the dummy gate electrode DG and the plurality of dummy nanosheets DNW. The dummy gate insulating layer 132 may be disposed between the dummy gate electrode DG and each of the first to sixth active patterns F1 to F6. The dummy gate insulating layer 132 may be disposed between the dummy gate electrode DG and the dummy gate spacer 131 on the field insulating layer 105. However, for example, the dummy gate insulating layer 132 may not be disposed between the dummy gate electrode DG and the dummy gate spacer 131 on the uppermost dummy nanosheet among the plurality of dummy nanosheets DNW, but the present disclosure is not limited thereto. The dummy gate insulating layer 132 may be disposed between the dummy gate electrode DG and the field insulating layer 105. The dummy gate insulating layer 132 may be disposed between the dummy gate electrode DG and each of the first to sixth source/drain regions to be described later.

Each of the gate insulating layer 122 and the dummy gate insulating layer 132 may include at least one of silicon oxide, silicon oxynitride, silicon nitride, or a high-k material having a dielectric constant greater than that of silicon oxide. The high-k material may include, for example, at least one hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide and lead zinc niobate.

The capping pattern 123 may extend in the second horizontal direction DR2 on each of the first to eighth gate electrodes G1 to G8. For example, the capping pattern 123 may be in contact with each of the uppermost surface of the gate spacer 121 and the uppermost surface of the gate insulating layer 122, but the present disclosure is not limited thereto. In some other embodiments, the capping pattern 123 may be disposed between the gate spacers 121.

The dummy capping pattern 133 may extend in the second horizontal direction DR2 on the dummy gate electrode DG. For example, the dummy capping pattern 133 may be in contact with the uppermost surface of the dummy gate spacer 131, but the present disclosure is not limited thereto.

Each of the capping pattern 123 and the dummy capping pattern 133 may include, for example, at least one of silicon nitride (SiN), silicon oxynitride (SiON), silicon oxide (SiO₂), silicon carbonitride (SiCN), silicon oxycarbonitride (SiOCN), or a combination thereof.

The first gate cut GC1 may be disposed between the second active pattern F2 and the third active pattern F3. The first gate cut GC1 may be provided in the first cell region R1. The first gate cut GC1 may separate the first gate electrode G1 from the second gate electrode G2. The first gate cut GC1 may be wider than the first gate electrode G1 and the second gate electrode GC2 in the first horizontal direction DR1. The second gate cut GC2 may be disposed between the first active pattern F1 and the second active pattern F2. The second gate cut GC2 may separate the third gate electrode G3 from the fourth gate electrode G4. The third gate cut GC3 may be disposed between the fourth active pattern F4 and the fifth active pattern F5. The third gate cut GC3 may separate the fifth gate electrode G5 from the sixth gate electrode G6. The fourth gate cut GC4 may be disposed between the fifth active pattern F5 and the sixth active pattern F6. The fourth gate cut GC4 may separate the seventh gate electrode G7 from the eighth gate electrode G8.

Each of the first to fourth gate cuts GC1 to GC4 may extend into the field insulating layer 105. For example, the first to fourth gate cuts GC1 to GC4 may be formed on the same plane as the top surface of the capping pattern 123. However, the present disclosure is not limited thereto. Each of the first to fourth gate cuts GC1 to GC4 may include one of, for example, silicon nitride (SiN), silicon oxynitride (SiON), silicon oxide (SiO₂), silicon oxynitride (SiOCN), and a combination thereof. However, the present disclosure is not limited thereto.

Each of the first and second active cuts FC1 and FC2 may be disposed on the boundary line of the first cell region R1 extending in the second horizontal direction DR2. For example, the first active cut FC1 may be disposed on a first boundary line of the first cell region R1 and the second active cut FC2 may be disposed on a second boundary line of the first cell region R1 opposite the first boundary line. Each of the second and third active cuts FC2 and FC3 may be disposed on the boundary line of the second cell region R2 extending in the second horizontal direction DR2. The second active cut FC2 may be disposed on the boundary line between the first cell region R1 and the second cell region R2.

Each of the first to third active cuts FC1, FC2, and FC3 may extend in the second horizontal direction DR2. For example, each of the first to third active cuts FC1, FC2, and FC3 may extend into the substrate 100 while penetrating the dummy capping pattern 133, the dummy gate electrode DG, and the plurality of dummy nanosheets DNW in the vertical direction DR3 between the dummy gate spacers 131. In other words, the bottom surface of each of the first to third active cuts FC1, FC2, and FC3 may be formed inside the substrate 100.

For example, the sidewalls of the first to third active cuts FC1, FC2, and FC3 may be in contact with the plurality of dummy nanosheets DNW. For example, between the plurality of dummy nanosheets DNW, the sidewalls of the first to third active cuts FC1, FC2, and FC3 may be in contact with each of the dummy gate insulating layer 132 and the dummy gate electrode DG. For example, on the uppermost dummy nanosheet among the plurality of dummy nanosheets DNW, the sidewalls of the first to third active cuts FC1, FC2, and FC3 may be in contact with the dummy gate spacer 131. For example, the top surfaces of the first to third active cuts FC1, FC2, and FC3 may be formed on the same plane as the top surface of the dummy capping pattern 133, but the present disclosure is not limited thereto.

The first active cut FC1 may be disposed on the first sidewalls of the first to third active patterns F1, F2, and F3. The second active cut FC2 may be disposed between the second sidewalls of the first to third active patterns F1, F2, and F3 and the first sidewalls of the fourth to sixth active patterns F4, F5, and F6. Here, the second sidewalls of the first to third active patterns F1, F2, and F3 may be the sidewalls facing the first sidewalls of the first to third active patterns F1, F2, and F3 in the first horizontal direction DR1. The third active cut FC3 may be disposed on the second sidewalls of the fourth to sixth active patterns F4, F5, and F6. Here, the second sidewalls of the fourth to sixth active patterns F4, F5, and F6 may be the sidewalls facing the first sidewalls of the fourth to sixth active patterns F4, F5, and F6 in the first horizontal direction DR1.

For example, the second active cut FC2 may separate the first active pattern F1 from the fourth active pattern F4. The second active cut FC2 may separate the second active pattern F2 from the fifth active pattern F5. The second active cut FC2 may separate the third active pattern F3 from the sixth active pattern F6. The second active cut FC2 may be in contact with each of the first to sixth active patterns F1 to F6.

For example, the pitch in the first horizontal direction DR1 between the center of the first active cut FC1 and the center of the first gate electrode G1, the pitch in the first horizontal direction DR1 between the center of the first gate electrode G1 and the center of the third gate electrode G3, the pitch in the first horizontal direction DR1 between the center of the third gate electrode G3 and the center of the second active cut FC2, the pitch in the first horizontal direction DR1 between the center of the second active cut FC2 and the center of the fifth gate electrode G5, the pitch in the first horizontal direction DR1 between the center of the fifth gate electrode G5 and the center of the seventh gate electrode G7, and the pitch in the first horizontal direction DR1 between the center of the seventh gate electrode G7 and the center of the third active cut FC3 may be the same. However, the present disclosure is not limited thereto.

Each of the first to third active cuts FC1, FC2, and FC3 may include one of, for example, silicon nitride (SiN), silicon oxynitride (SiON), silicon oxide (SiO₂), silicon oxynitride (SiOCN), and a combination thereof. However, the present disclosure is not limited thereto.

A first source/drain region SD1 may be disposed on both sides of each of the first gate electrode G1 and the third gate electrode G3 on the first active pattern F1. The first source/drain region SD1 may be in direct contact with the first active pattern F1. A second source/drain region SD2 may be disposed on both sides of each of the first gate electrode G1 and the fourth gate electrode G4 on the second active pattern F2. A third source/drain region SD3 may be disposed on both sides of each of the second gate electrode G2 and the fourth gate electrode G4 on the third active pattern F3.

A fourth source/drain region may be disposed on both sides of each of the fifth gate electrode G5 and the seventh gate electrode G7 on the fourth active pattern F4. A fifth source/drain region SD5 may be disposed on both sides of each of the sixth gate electrode G6 and the seventh gate electrode G7 on the fifth active pattern F5. A sixth source/drain region may be disposed on both sides of each of the seventh gate electrode G7 and the eighth gate electrode G8 on the sixth active pattern F6.

The first to sixth source/drain regions may be in contact with the first to sixth pluralities of nanosheets, respectively. Each of the first to sixth source/drain regions may be in contact with the plurality of dummy nanosheets. Each of the first to sixth source/drain regions may be in contact with the gate insulating layer 122. However, the present disclosure is not limited thereto. In some other embodiments of the present disclosure, an inner spacer may be disposed between each of the first to sixth source/drain regions and the gate insulating layer 122. Each of the first to sixth source/drain regions may be in contact with the dummy gate insulating layer 132.

A first pull-down transistor PD1 may be formed at the portion where the first active pattern F1 and the first gate electrode G1 intersect. A first pull-up transistor PU1 may be formed at the portion where the second active pattern F2 and the first gate electrode G1 intersect. A first pass transistor PG1 may be formed at the portion where the first active pattern F1 and the third gate electrode G3 intersect. A second pull-down transistor PD2 may be formed at the portion where the third active pattern F3 and the fourth gate electrode G4 intersect. A second pull-up transistor PU2 may be formed at the portion where the second active pattern F2 and the fourth gate electrode G4 intersect. A second pass transistor PG2 may be formed at the portion where the third active pattern F3 and the second gate electrode G2 intersect.

A third pull-down transistor PD3 may be formed at the portion where the fourth active pattern F4 and the seventh gate electrode G7 intersect. A third pull-up transistor PU3 may be formed at the portion where the fifth active pattern F5 and the seventh gate electrode G7 intersect. A third pass transistor PG3 may be formed at the portion where the fourth active pattern F4 and the fifth gate electrode G5 intersect. A fourth pull-down transistor PD4 may be formed at the portion where the sixth active pattern F6 and the sixth gate electrode G6 intersect. A fourth pull-up transistor PU4 may be formed at the portion where the fifth active pattern F5 and the sixth gate electrode G6 intersect. A fourth pass transistor PG4 may be formed at the portion where the sixth active pattern F6 and the eighth gate electrode G8 intersect.

Each of the first to fourth pull-down transistors PD1 to PD4 may be an NMOS transistor, and each of the first to fourth pull-up transistors PU1 to PU4 may be a PMOS transistor. Each of the first to fourth pull-up transistors PU1 to PU4 may be aligned in the first horizontal direction DR1. The second and fourth pull-up transistors PU2 and PU4 face each other with the second active cut FC2 therebetween.

A first lower source/drain contact BCA1 may be disposed between the first active cut FC1 and the first gate electrode G1. The first lower source/drain contact BCA1 may penetrate the substrate 100 and the first active pattern F1 in the vertical direction DR3 to extend into the first source/drain region SD1. The first lower source/drain contact BCA1 may be connected to the first buried rail VSS1 that is the first ground rail. The top surface and at least a part of the sidewall of the first lower source/drain contact BCA1 may be electrically connected to the first source/drain region SD1.

The second lower source/drain contact BCA2 may be disposed between the first gate electrode G1 and the fourth gate electrode G4. The second lower source/drain contact BCA2 may penetrate the substrate 100 and the second active pattern F2 in the vertical direction DR3 to extend into the second source/drain region SD2. The second lower source/drain contact BCA2 may be connected to the second buried rail VDD that is the power rail. For example, the second lower source/drain contact BCA2 may be in direct contact with the second buried rail VDD. The top surface and at least a part of the sidewall of the second lower source/drain contact BCA2 may be electrically connected to the second source/drain region SD2.

The third lower source/drain contact BCA3 may be disposed between the fourth gate electrode G4 and the second active cut FC2. The third lower source/drain contact BCA3 may penetrate the substrate 100 and the third active pattern F3 in the vertical direction DR3 to extend into the third source/drain region SD3. The third lower source/drain contact BCA3 may be connected to the third buried rail VSS2 that is the second ground rail. The top surface and at least a part of the sidewall of the third lower source/drain contact BCA3 may be electrically connected to the third source/drain region SD3.

The fourth lower source/drain contact BCA4 may be disposed between the second active cut FC2 and the sixth gate electrode G6. The fourth lower source/drain contact BCA4 may penetrate the substrate 100 and the sixth active pattern F6 in the vertical direction DR3 to extend into the sixth source/drain region. The fourth lower source/drain contact BCA4 may be connected to the third buried rail VSS2 that is the second ground rail. The top surface and at least a part of the sidewall of the fourth lower source/drain contact BCA4 may be electrically connected to the sixth source/drain region.

The fifth lower source/drain contact BCA5 may be disposed between the sixth gate electrode G6 and the seventh gate electrode G7. The fifth lower source/drain contact BCA5 may penetrate the substrate 100 and the fifth active pattern F5 in the vertical direction DR3 to extend into the fifth source/drain region SD5. The fifth lower source/drain contact BCA5 may be connected to the second buried rail VDD that is the power rail. For example, the fifth lower source/drain contact BCA5 may be in direct contact with the second buried rail VDD. The top surface and at least a part of the sidewall of the fifth lower source/drain contact BCA5 may be electrically connected to the fifth source/drain region SD5.

The sixth lower source/drain contact BCA6 may be disposed between the seventh gate electrode G7 and the third active cut FC3. The sixth lower source/drain contact BCA6 may penetrate the substrate 100 and the sixth active pattern F6 in the vertical direction DR3 to extend into the fourth source/drain region. The sixth lower source/drain contact BCA6 may be connected to the first buried rail VSS1 that is the first ground rail. The top surface and at least a part of the sidewall of the sixth lower source/drain contact BCA6 may be electrically connected to the fourth source/drain region.

The positions of the first to sixth lower source/drain contacts BCA1 to BCA6 illustrated in FIGS. 1 and 4 are examples. For example, in some other embodiments of the present disclosure, the positions of the first to sixth lower source/drain contacts BCA1 to BCA6 may vary. Each of the first to sixth lower source/drain contacts BCA1 to BCA6 may include a conductive material. A silicide layer may be disposed between each of the first to sixth lower source/drain contacts BCA1 to BCA6 and each of the first to sixth source/drain regions. The silicide layer may include, for example, a metal silicide material.

For example, the first pull-down transistor PD1 may be electrically connected to the first buried rail VSS1 that is the first ground rail through the first lower source/drain contact BCA1. The second pull-down transistor PD2 may be electrically connected to the third buried rail VSS2 that is the second ground rail through the third lower source/drain contact BCA3. The third pull-down transistor PD3 may be electrically connected to the first buried rail VSS1 that is the first ground rail through the sixth lower source/drain contact BCA6. The fourth pull-down transistor PD4 may be electrically connected to the third buried rail VSS2 that is the second ground rail through the fourth lower source/drain contact BCA4.

For example, each of the first pull-up transistor PU1 and the second pull-up transistor PU2 may be electrically connected to the second buried rail VDD that is the power rail through the second lower source/drain contact BCA2. Each of the third pull-up transistor PU3 and the fourth pull-up transistor PU4 may be electrically connected to the second buried rail VDD that is the power rail through the fifth lower source/drain contact BCA5.

The first upper interlayer insulating layer 140 may be disposed on the field insulating layer 105. The first upper interlayer insulating layer 140 may surround the first to sixth source/drain regions. The first upper interlayer insulating layer 140 may surround the sidewall of the gate spacer 121 and the sidewall of the dummy gate spacer 131. For example, the first upper interlayer insulating layer 140 may surround the sidewall of the capping pattern 123 and the sidewall of the dummy capping pattern 133.

For example, the top surface of the first upper interlayer insulating layer 140 may be formed on the same plane as the top surface of the capping pattern 123, the top surface of the dummy capping pattern 133, the top surface of each of the first to third active cuts FC1, FC2, and FC3, and the top surface of each of the first to fourth gate cuts GC1 to GC4. However, the present disclosure is not limited thereto. The first upper interlayer insulating layer 140 may include, for example, at least one of silicon oxide, silicon nitride, silicon oxynitride, or a low-k material.

The first gate contact CB1 may penetrate the capping pattern 123 in the vertical direction DR3 to be connected to the first gate electrode G1. The first gate contact CB1 may be adjacent to the first gate cut GC1. The second gate contact CB2 may penetrate the capping pattern 123 in the vertical direction DR3 to be connected to the second gate electrode G2. The third gate contact CB3 may penetrate the capping pattern 123 in the vertical direction DR3 to be connected to the third gate electrode G3. The fourth gate contact CB4 may penetrate the capping pattern 123 in the vertical direction DR3 to be connected to the fourth gate electrode G4. For example, the fourth gate contact CB4 may be in direct contact with the fourth gate electrode G4.

Further, the fifth gate contact CB5 may penetrate the capping pattern 123 in the vertical direction DR3 to be connected to the fifth gate electrode G5. The sixth gate contact CB6 may penetrate the capping pattern 123 in the vertical direction DR3 to be connected to the sixth gate electrode G6. The seventh gate contact CB7 may penetrate the capping pattern 123 in the vertical direction DR3 to be connected to the seventh gate electrode G7. The eighth gate contact CB8 may penetrate the capping pattern 123 in the vertical direction DR3 to be connected to the eighth gate electrode G8.

The positions of the first to eighth gate contacts CB1 to CB8 illustrated in FIGS. 1 and 4 are examples. For example, in some other embodiments of the present disclosure, the positions of the first to eighth gate contacts CB1 to CB8 may vary. Each of the first to eighth gate contacts CB1 to CB8 may include a conductive material. For example, the top surface of each of the first to eighth gate contacts CB1 to CB8 may be formed on the same plane as the top surface of the first upper interlayer insulating layer 140. However, the present disclosure is not limited thereto.

The first upper source/drain contact UCA1 may be disposed between the first active cut FC1 and the first gate electrode G1. The first upper source/drain contact UCA1 may penetrate the first upper interlayer insulating layer 140 in the vertical direction DR3 to be connected to the second source/drain region SD2. The second upper source/drain contact UCA2 may be disposed between the first active cut FC1 and the second gate electrode G2. The second upper source/drain contact UCA2 may penetrate the first upper interlayer insulating layer 140 in the vertical direction DR3 to be connected to the third source/drain region SD3.

The third upper source/drain contact UCA3 may be disposed between the first gate electrode G1 and the third gate electrode G3. The third upper source/drain contact UCA3 may penetrate the first upper interlayer insulating layer 140 in the vertical direction DR3 to be connected to the first source/drain region SD1. The fourth upper source/drain contact UCA4 may be disposed between the second gate electrode G2 and the fourth gate electrode G4. The fourth upper source/drain contact UCA4 may penetrate the first upper interlayer insulating layer 140 in the vertical direction DR3 to be connected to the third source/drain region SD3.

The fifth upper source/drain contact UCA5 may be disposed between the third gate electrode G3 and the second active cut FC2. The fifth upper source/drain contact UCA5 may penetrate the first upper interlayer insulating layer 140 in the vertical direction DR3 to be connected to the first source/drain region SD1. The sixth upper source/drain contact UCA6 may be disposed between the fourth gate electrode G4 and the second active cut FC2. The sixth upper source/drain contact UCA6 may penetrate the first upper interlayer insulating layer 140 in the vertical direction DR3 to be connected to the second source/drain region SD2. The sixth upper source/drain contact UCA6 may protrude into the second source/drain region SD2.

The seventh upper source/drain contact UCA7 may be disposed between the second active cut FC2 and the fifth gate electrode G5. The seventh upper source/drain contact UCA7 may penetrate the first upper interlayer insulating layer 140 in the vertical direction DR3 to be connected to the fourth source/drain region. The eighth upper source/drain contact UCA8 may be disposed between the second active cut FC2 and the sixth gate electrode G6. The eighth upper source/drain contact UCA8 may penetrate the first upper interlayer insulating layer 140 in the vertical direction DR3 to be connected to the fifth source/drain region SD5. The eighth upper source/drain contact UCA8 may protrude into the fifth source/drain region SD5.

The ninth upper source/drain contact UCA9 may be disposed between the fifth gate electrode G5 and the seventh gate electrode G7. The ninth upper source/drain contact UCA9 may penetrate the first upper interlayer insulating layer 140 in the vertical direction DR3 to be connected to the fourth source/drain region. The tenth upper source/drain contact UCA10 may be disposed between the sixth gate electrode G6 and the eighth gate electrode G8. The tenth upper source/drain contact UCA10 may penetrate the first upper interlayer insulating layer 140 in the vertical direction DR3 to be connected to the sixth source/drain region.

The eleventh upper source/drain contact UCA11 may be disposed between the seventh gate electrode G7 and the third active cut FC3. The eleventh upper source/drain contact UCA11 may penetrate the first upper interlayer insulating layer 140 in the vertical direction DR3 to be connected to the fifth source/drain region SD5. The twelfth upper source/drain contact UCA12 may be disposed between the eighth gate electrode G8 and the third active cut FC3. The twelfth upper source/drain contact UCA12 may penetrate the first upper interlayer insulating layer 140 in the vertical direction DR3 to be connected to the sixth source/drain region.

The positions of the first to twelfth upper source/drain contacts UCA1 to UCA12 illustrated in FIGS. 1 and 4 are examples. For example, in some other embodiments of the present disclosure, the positions of the first to twelfth upper source/drain contacts UCA1 to UCA12 may vary. Each of the first to twelfth upper source/drain contacts UCA1 to UCA12 may include a conductive material. For example, the top surface of each of the first to twelfth upper source/drain contacts UCA1 to UCA12 may be formed on the same plane as the top surface of the first upper interlayer insulating layer 140. However, the present disclosure is not limited thereto. The silicide layer may be disposed between each of the first to twelfth upper source/drain contacts UCA1 to UCA12 and each of the first to sixth source/drain regions. The silicide layer may include, for example, a metal silicide material.

The etch stop layer 150 may be disposed on the first upper interlayer insulating layer 140. Although it is depicted in FIGS. 5 to 7 that the etch stop layer 150 is formed as a single layer, the present disclosure is not limited thereto. In some other embodiments of the present disclosure, the etch stop layer 150 may be formed as a multilayer. The etch stop layer 150 may include, for example, at least one of aluminum oxide, aluminum nitride, hafnium oxide, zirconium oxide, silicon oxide, silicon nitride, silicon oxynitride, or a low-k material. The second upper interlayer insulating layer 160 may be disposed on the etch stop layer 150. The second upper interlayer insulating layer 160 may include, for example, at least one of silicon oxide, silicon nitride, silicon oxynitride, or a low-k material.

In the semiconductor device according to some embodiments of the present disclosure, a degree of integration of the semiconductor device may be increase by forming two pull-up transistors, e.g., PU1 and PU2, on one active pattern, e.g., F2, in one cell region, e.g., R1, to reduce the number of active patterns disposed in the one cell region R1.

Further, in the semiconductor device according to some embodiments of the present disclosure, a degree of integration of the semiconductor device may be increased by disposing the second active cut FC2 between two pull-up transistors, e.g., PU1 and PU2, disposed in the first cell region R1 and two pull-up transistors, e.g., PU3 and PU4, disposed in the second cell region R2 adjacent to the first cell region R1, and arranging the two pull-up transistors PU1 and PU2 disposed in the first cell region R1 and the two pull-up transistors PU3 and PU4 disposed in the second cell region R2 to be aligned in the first horizontal direction DR1.

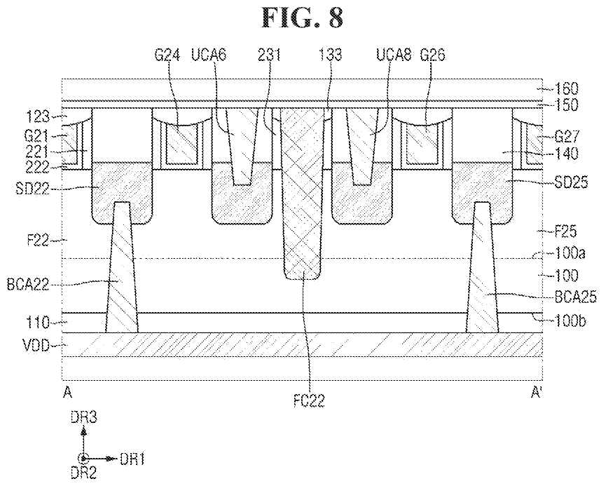

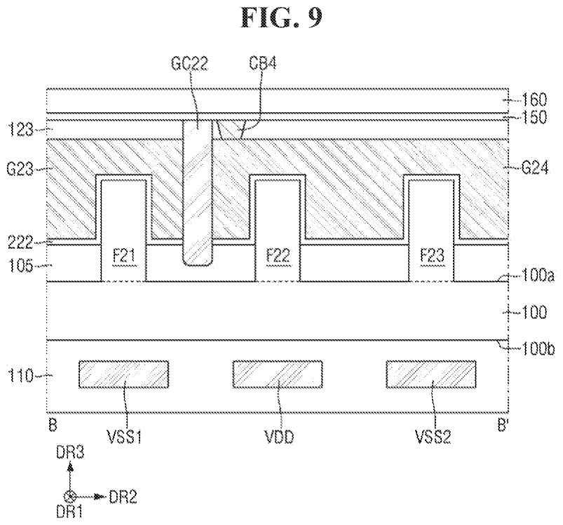

Hereinafter, a semiconductor device according to some other embodiments of the present disclosure will be described with reference to FIGS. 8 to 10. Differences from the semiconductor device shown in FIGS. 1 to 7 will be mainly described.

FIGS. 8 to 10 are cross-sectional views illustrating a semiconductor device according to some other embodiments of the present disclosure.

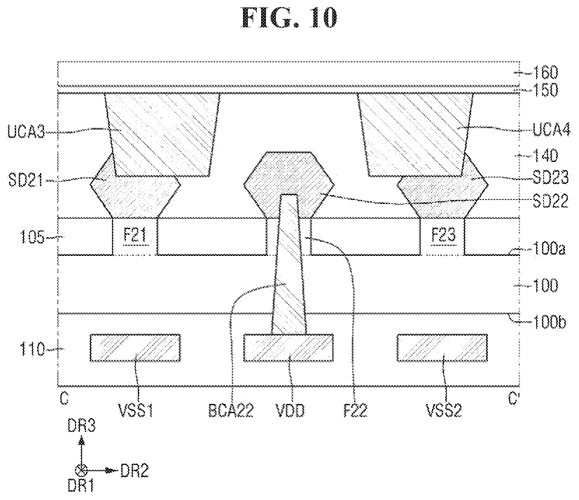

Referring to FIGS. 8 and 10, a semiconductor device according to some other embodiments of the present disclosure may have a fin-type transistor (FinFET) structure. The layout structure of the semiconductor device illustrated in FIGS. 8 to 10 may be the same as the layout structure of the semiconductor device illustrated in FIGS. 1 to 4. Accordingly, hereinafter, the cross-sectional structure of the semiconductor device shown in FIGS. 8 to 10 will be mainly described.

For example, the gate insulating layer 222 may be disposed between each of a plurality of active patterns F21, F22, F23, and F25 and each of a plurality of gate electrodes G21, G23, G24, G26, and G27. Further, the gate insulating layer 222 may be disposed between each of the plurality of gate electrodes G21, G23, G24, G26, and G27 and the field insulating layer 105. The gate spacer 221 may extend in the second horizontal direction DR2 along both sidewalls of each of the plurality of gate electrodes G21, G23, G24, G26, and G27.

For example, a second gate cut GC22 may separate the third gate electrode G23 from the fourth gate electrode G24. For example, the second gate cut GC22 may be sandwiched between the third gate electrode G23 from the fourth gate electrode G24. For example, a second active cut FC22 may separate the second active pattern F22 from the fifth active pattern F25. For example, the dummy gate spacer 231 may extend in the second horizontal direction DR2 along both sidewalls of the second active cut FC22. The dummy gate spacer 231 may be in contact with each of a part of the top surface of the second active pattern F22 adjacent to the second active cut FC22 and a part of the top surface of the fifth active pattern F25.

For example, a first source/drain region SD21, a second source/drain region SD22, a third source/drain region SD23, and a fifth source/drain region SD25 may be disposed on the first active pattern F21, the second active pattern F22, the third active pattern F23, and the fifth active pattern F25, respectively.

For example, a second lower source/drain contact BCA22 may penetrate the substrate 100 and the second active pattern F22 in the vertical direction DR3 to extend into the second source/drain region SD22. For example, the second lower source/drain contact BCA22 may penetrate into the second source/drain region SD22. The second lower source/drain contact BCA22 may be connected to the second buried rail VDD that is the power rail. A fifth lower source/drain contact BCA25 may penetrate the substrate 100 and the fifth active pattern F25 in the vertical direction DR3 to extend into the fifth source/drain region SD25. The fifth lower source/drain contact BCA25 may be connected to the second buried rail VDD that is the power rail.

For example, at least a part of the second active pattern F22 may be disposed between the second active cut FC22 and the second source/drain region SD22. Further, at least a part of the fifth active pattern F25 may be disposed between the second active cut FC22 and the fifth source/drain region SD25.

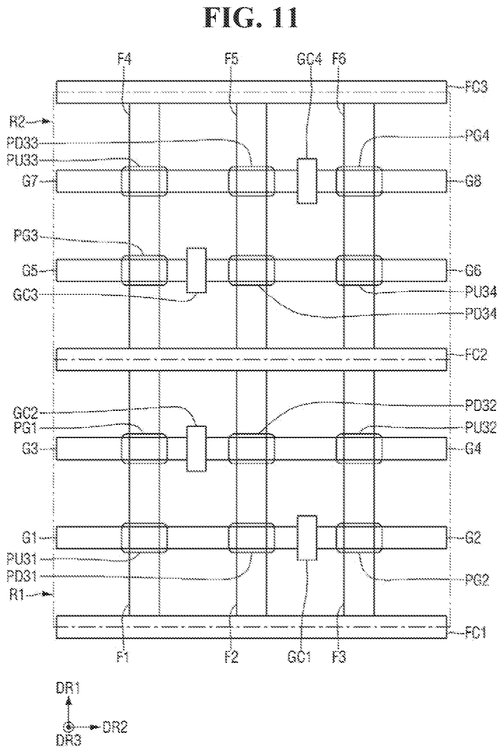

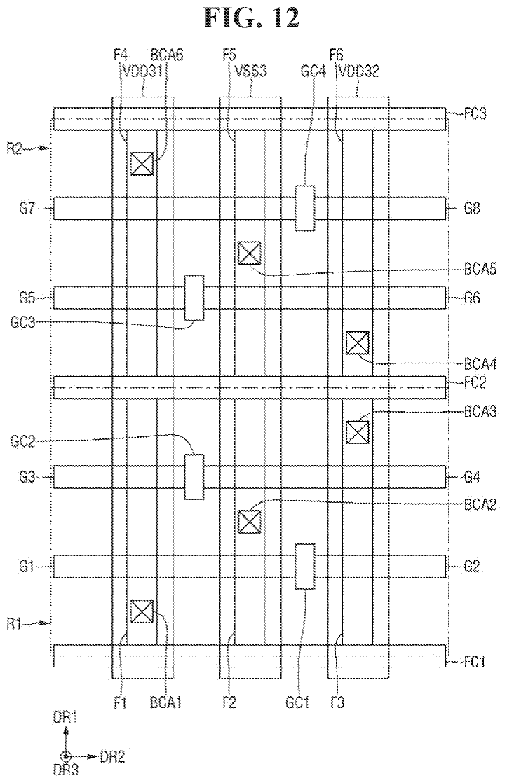

Hereinafter, a semiconductor device according to some other embodiments of the present disclosure will be described with reference to FIGS. 11 and 12. Differences from the semiconductor device shown in FIGS. 1 to 7 will be mainly described.

FIGS. 11 and 12 are layout diagrams illustrating a semiconductor device according to some other embodiments of the present disclosure.

Referring to FIGS. 11 and 12, in a semiconductor device according to some other embodiments of the present disclosure, a first buried rail VDD31 may be a first power rail, a second buried rail VSS3 may be a ground rail, and a third buried rail VDD32 may be a second power rail.

For example, the first buried rail VDD31 that is the first power rail may overlap each of the first active pattern F1 and the fourth active pattern F4 in the vertical direction DR3. The second buried rail VSS3 that is the ground rail may overlap each of the second active pattern F2 and the fifth active pattern F5 in the vertical direction DR3. The third buried rail VDD32 that is the second power rail may overlap each of the third active pattern F3 and the sixth active pattern F6 in the vertical direction DR3.

A first pull-up transistor PU31 may be formed at the portion where the first active pattern F1 and the first gate electrode G1 intersect. A first pull-down transistor PD31 may be formed at the portion where the second active pattern F2 and the first gate electrode G1 intersect. A second pull-up transistor PU32 may be formed at the portion where the third active pattern F3 and the fourth gate electrode G4 intersect. A second pull-down transistor PD32 may be formed at the portion where the second active pattern F2 and the fourth gate electrode G4 intersect.

A third pull-up transistor PU33 may be formed at the portion where the fourth active pattern F4 and the seventh gate electrode G7 intersect. A third pull-down transistor PD33 may be formed at the portion where the fifth active pattern F5 and the seventh gate electrode G7 intersect. A fourth pull-up transistor PU34 may be formed at the portion where the sixth active pattern F6 and the sixth gate electrode G6 intersect. A fourth pull-down transistor PD34 may be formed at the portion where the fifth active pattern F5 and the sixth gate electrode G6 intersect.

Each of the first to fourth pull-down transistors PD31 to PD34 may be an NMOS transistor, and each of the first to fourth pull-up transistors PU31 to PU34 may be a PMOS transistor. Each of the first to fourth pull-down transistors PD1 to PD4 may be aligned in the first horizontal direction DR1.

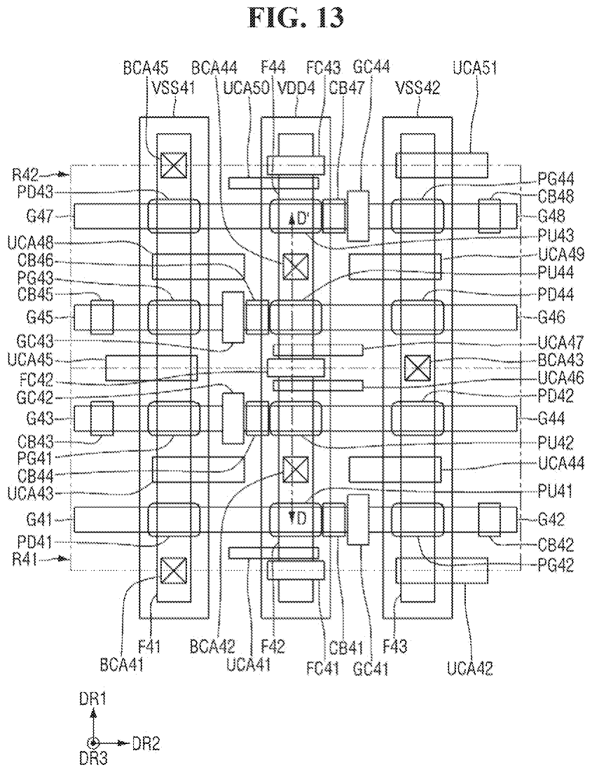

Hereinafter, a semiconductor device according to still other embodiments of the present disclosure will be described with reference to FIGS. 13 to 17. Differences from the semiconductor device shown in FIGS. 1 to 7 will be mainly described.

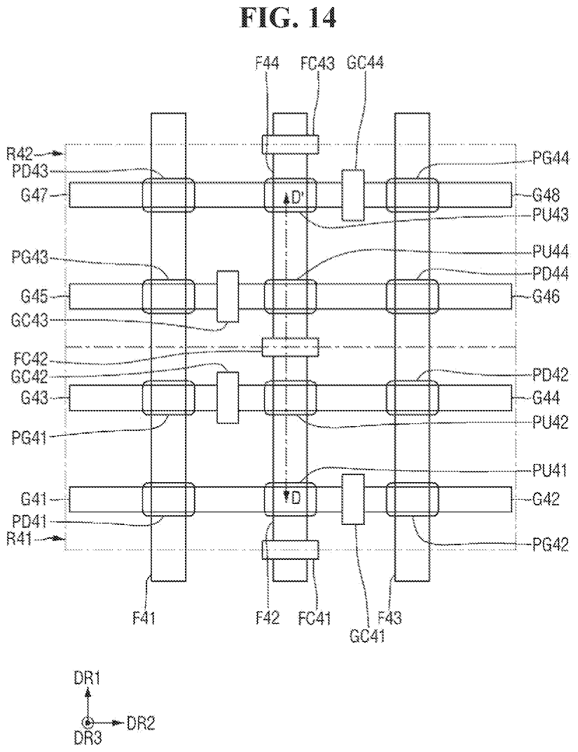

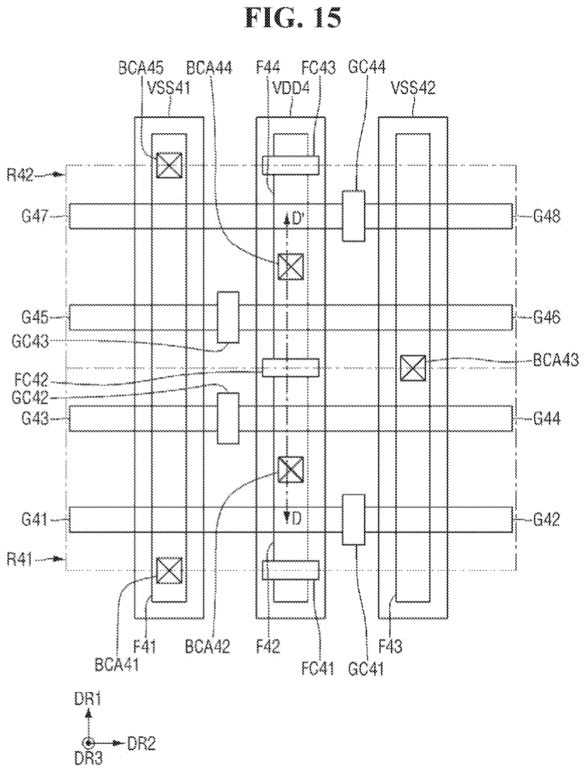

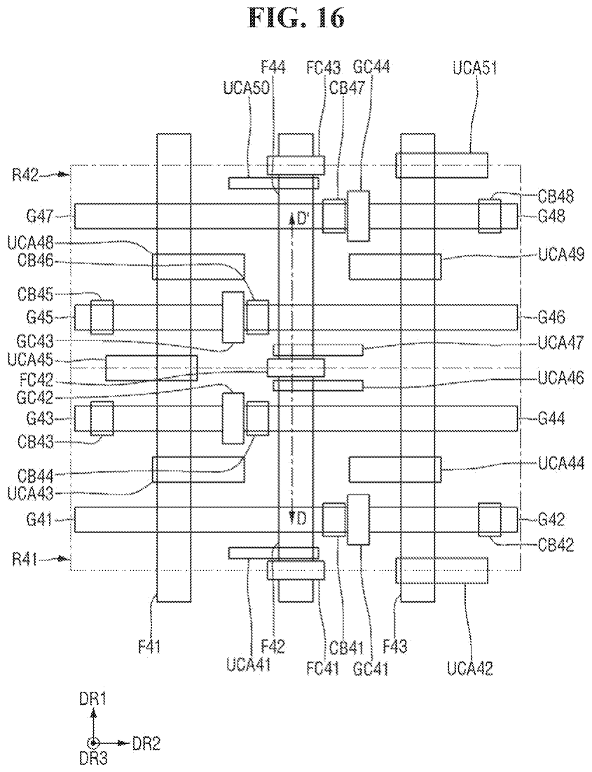

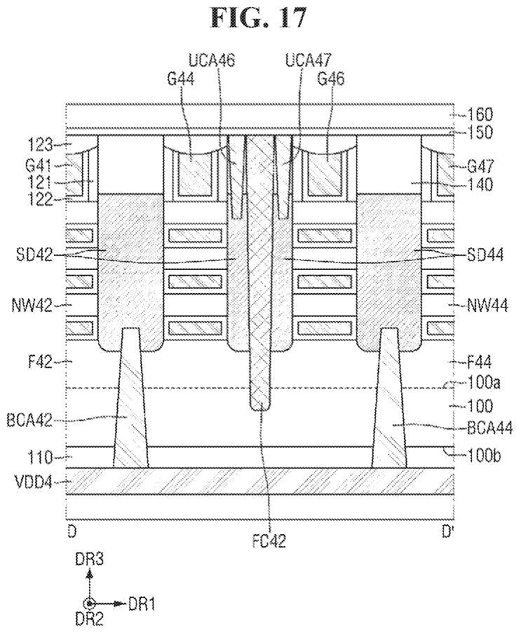

FIG. 13 is a layout diagram illustrating a semiconductor device according to still other embodiments of the present disclosure. FIG. 14 is a layout diagram illustrating arrangement of a plurality of transistors in FIG. 13. FIG. 15 is a layout diagram illustrating a connection relationship between buried rails in FIG. 13. FIG. 16 is a layout diagram illustrating a connection relationship between a gate contact and an upper source/drain contact in FIG. 13. FIG. 17 is a cross-sectional view taken along line D-D′ in each of FIGS. 13 to 16.

Referring to FIGS. 13 to 17, a semiconductor device according to some other embodiments of the present disclosure includes a first cell region R41, a second cell region R42, first, second, third and fourth active patterns F41, F42, F43 and F44, a first buried rail VSS41, a second buried rail VDD4, a third buried rail VSS42, first, second, third and fourth pluralities of nanosheets, first, second, third, fourth, fifth, sixth, seventh and eighth gate electrodes G41, G42, G43, G44, G45, G46, G47 and G48, first, second, third and fourth source/drain regions, first, second, third and fourth gate cuts GC41, GC42, GC43 and GC44, first, second and third active cuts FC41, FC42, and FC43, first, second, third and fourth pull-down transistors PD41, PD42, PD43 and PD44, first, second, third and fourth pull-up transistors PU41, PU42, PU43 and PU44, first, second, third and fourth pass transistors PG41 to PG44, first, second, third, fourth, fifth, sixth, seventh and eighth gate contacts CB41, CB42, CB43, CB44, CB45, CB46, CB47 and CB48, first, second, third, fourth, fifth, sixth, seventh, eighth, ninth, tenth and eleventh upper source/drain contacts UCA41, UCA42, UCA43, UCA44, UCA45, UCA46, UCA47, UCA48, UCA49, UCA50 and UCA51, and first, second, third, fourth and fifth lower source/drain contacts BCA41, BCA42, BCA43, BCA44 and BCA45.

The first active pattern F41 may continuously extend in the first horizontal direction DR1 on the first cell region R41 and the second cell region R42. The second active pattern F42 may extend in the first horizontal direction DR1 on the first cell region R41. The second active pattern F42 may be spaced apart from the first active pattern F41 in the second horizontal direction DR2. The second active pattern F42 may be disposed between the first active pattern F41 and the third active pattern F43. The third active pattern F43 may continuously extend in the first horizontal direction DR1 on the first cell region R41 and the second cell region R42. The third active pattern F43 may be spaced apart from the second active pattern F42 in the second horizontal direction DR2. The fourth active pattern F44 may extend in the first horizontal direction DR1 on the second cell region R42. The fourth active pattern F44 may be disposed between the first active pattern F41 and the third active pattern F43. The fourth active pattern F44 may be spaced apart from the second active pattern F42 in the first horizontal direction DR1.

For example, the first buried rail VSS41 that is the first ground rail may extend in the first horizontal direction DR1 across the first cell region R41 and the second cell region R42. The first buried rail VSS41 may overlap the first active pattern F41 in the vertical direction DR3. For example, the second buried rail VDD4 that is the power rail may extend in the first horizontal direction DR1 across the first cell region R1 and the second cell region R2. The second buried rail VDD4 may overlap each of the second active pattern F42 and the fourth active pattern F44 in the vertical direction DR3. For example, the third buried rail VSS42 that is the second ground rail may extend in the first horizontal direction DR1 across the first cell region R1 and the second cell region R2. The third buried rail VSS42 may overlap the third active pattern F43 in the vertical direction DR3.

Each of the first to fourth gate electrodes G41 to G44 may be disposed in the first cell region R41. For example, the first gate electrode G41 may extend in the second horizontal direction DR2 on the first active pattern F41 and the second active pattern F42. The second gate electrode G42 may extend in the second horizontal direction DR2 on the third active pattern F43. The second gate electrode G42 may be spaced apart from the first gate electrode G41 in the second horizontal direction DR2.

For example, the third gate electrode G43 may extend in the second horizontal direction DR2 on the first active pattern F41. The third gate electrode G43 may be spaced apart from the first gate electrode G41 in the first horizontal direction DR1. The fourth gate electrode G44 may extend in the second horizontal direction DR2 on the second active pattern F42 and the third active pattern F43. The fourth gate electrode G44 may be spaced apart from the third gate electrode G43 in the second horizontal direction DR2. The fourth gate electrode G44 may be spaced apart from each of the first gate electrode G41 and the second gate electrode G42 in the first horizontal direction DR1.

Each of the fifth to eighth gate electrodes G45 to G48 may be disposed in the second cell region R42. For example, the fifth gate electrode G45 may extend in the second horizontal direction DR2 on the first active pattern F41. The fifth gate electrode G45 may be spaced apart from the third gate electrode G43 in the first horizontal direction DR1. The sixth gate electrode G46 may extend in the second horizontal direction DR2 on the fourth active pattern F44 and the third active pattern F43. The sixth gate electrode G46 may be spaced apart from the fifth gate electrode G45 in the second horizontal direction DR2. The sixth gate electrode G46 may be spaced apart from the fourth gate electrode G44 in the first horizontal direction DR1.

For example, the seventh gate electrode G47 may extend in the second horizontal direction DR2 on the first active pattern F41 and the fourth active pattern F44. The seventh gate electrode G47 may be spaced apart from each of the fifth gate electrode G45 and the sixth gate electrode G46 in the first horizontal direction DR1. The eighth gate electrode G48 may extend in the second horizontal direction DR2 on the third active pattern F43. The eighth gate electrode G48 may be spaced apart from the seventh gate electrode G47 in the second horizontal direction DR2. The eighth gate electrode G48 may be spaced apart from the sixth gate electrode G46 in the first horizontal direction DR1.

For example, the pitch in the first horizontal direction DR1 between the center of the first gate electrode G41 and the center of the third gate electrode G43, the pitch in the first horizontal direction DR1 between the center of the third gate electrode G43 and the center of the fifth gate electrode G45, and the pitch in the first horizontal direction DR1 between the center of the fifth gate electrode G45 and the center of the seventh gate electrode G47 may be the same. However, the present disclosure is not limited thereto. In some other embodiments of the present disclosure, the pitch in the first horizontal direction DR1 between the center of the third gate electrode G43 and the center of the fifth gate electrode G45 may be greater than each of the pitch in the first horizontal direction DR1 between the center of the first gate electrode G41 and the center of the third gate electrode G43 and the pitch in the first horizontal direction DR1 between the center of the fifth gate electrode G45 and the center of the seventh gate electrode G47.

At the portion where each of the first to fourth active patterns F41 to F44 and each of the first to eighth gate electrodes G41 to G48 intersect, a plurality of nanosheets may be disposed on each of the first to fourth active patterns F41 to F44. For example, a second plurality of nanosheets NW42 may be disposed on the second active pattern F42. The second plurality of nanosheets NW42 may be disposed at the portion where the second active pattern F42 and the first gate electrode G41 intersect. Further, the second plurality of nanosheets NW42 may be disposed at the portion where the second active pattern F42 and the fourth gate electrode G44 intersect. The second plurality of nanosheets NW42 may include a plurality of nanosheets stacked while being spaced apart from each other in the vertical direction DR3 on the second active pattern F42. The second plurality of nanosheets NW42 may be surrounded by each of the first gate electrode G41 and the fourth gate electrode G44.

For example, a fourth plurality of nanosheets NW44 may be disposed on the fourth active pattern F44. The fourth plurality of nanosheets NW44 may be disposed at the portion where the fourth active pattern F44 and the sixth gate electrode G46 intersect. Further, the fourth plurality of nanosheets NW44 may be disposed at the portion where the fourth active pattern F44 and the seventh gate electrode G47 intersect. The fourth plurality of nanosheets NW44 may include a plurality of nanosheets stacked while being spaced apart from each other in the vertical direction DR3 on the fourth active pattern F44. The fourth plurality of nanosheets NW44 may be surrounded by each of the sixth gate electrode G46 and the seventh gate electrode G47.

The first gate cut GC41 may be disposed between the second active pattern F42 and the third active pattern F43. The first gate cut GC41 may separate the first gate electrode G41 from the second gate electrode G42. The second gate cut GC42 may be disposed between the first active pattern F41 and the second active pattern F42. The second gate cut GC42 may separate the third gate electrode G43 from the fourth gate electrode G44. The third gate cut GC43 may be disposed between the first active pattern F41 and the fourth active pattern F44. The third gate cut GC43 may separate the fifth gate electrode G45 from the sixth gate electrode G46. The fourth gate cut GC44 may be disposed between the fourth active pattern F44 and the third active pattern F43. The fourth gate cut GC44 may separate the seventh gate electrode G47 from the eighth gate electrode G48.

A first source/drain region may be disposed on both sides of each of the first gate electrode G41, the third gate electrode G43, the fifth gate electrode G45, and the seventh gate electrode G47 on the first active pattern F41. A second source/drain region SD42 may be disposed on both sides of each of the first gate electrode G41 and the fourth gate electrode G44 on the second active pattern F42. A third source/drain region may be disposed on both sides of each of the second gate electrode G42, the fourth gate electrode G44, the sixth gate electrode G46 and the eighth gate electrode G48 on the third active pattern F43. A fourth source/drain region SD44 may be disposed on both sides of each of the sixth gate electrode G46 and the seventh gate electrode G47 on the fourth active pattern F44.

Each of the first and second active cuts FC41 and FC42 may be disposed on the boundary line of the first cell region R41 extending in the second horizontal direction DR2. Each of the second and third active cuts FC42 and FC43 may be disposed on the boundary line of the second cell region R42 extending in the second horizontal direction DR2. The second active cut FC42 may be disposed on the boundary line between the first cell region R41 and the second cell region R42. In other words, the second active cut FC42 may identify a border between the first cell region R41 and the second cell region R42.

The second active cut FC42 may be disposed on the second buried rail VDD4. Each of the first to third active cuts FC41, FC42, and FC43 is not disposed on each of the first buried rail VSS41 and the second buried rail VSS42. For example, each of the first to third active cuts FC41, FC42, and FC43 may penetrate the first upper interlayer insulating layer 140 and a source/drain region in the vertical direction DR3 to extend into the substrate 100. For example, each of the first to third active cuts FC41, FC42, and FC43 may be aligned in the first horizontal direction DR1.

For example, the second active cut FC42 may separate the second active pattern F42 from the fourth active pattern F44. For example, the second active cut FC42 may pass through the second active pattern F42 from the fourth active pattern F44. The second active cut FC42 may be in contact with each of the second active pattern F42 and the fourth active pattern F44. For example, at least a part of the sidewall of the second active cut FC42 may be in contact with each of the second source/drain region SD42 and the fourth source/drain region SD44. Specifically, the first sidewall of the second active cut FC42 may be in contact with the second source/drain region SD42. Further, the second sidewall of the second active cut FC42 facing the first sidewall of the second active cut FC42 in the first horizontal direction DR1 may be in contact with the fourth source/drain region SD44.

The first pull-down transistor PD41 may be formed at the portion where the first active pattern F41 and the first gate electrode G41 intersect. The first pull-up transistor PU41 may be formed at the portion where the second active pattern F42 and the first gate electrode G41 intersect. The first pass transistor PG41 may be formed at the portion where the first active pattern F41 and the third gate electrode G43 intersect. The second pull-down transistor PD42 may be formed at the portion where the third active pattern F43 and the fourth gate electrode G44 intersect. The second pull-up transistor PU42 may be formed at the portion where the second active pattern F42 and the fourth gate electrode G44 intersect. The second pass transistor PG42 may be formed at the portion where the third active pattern F43 and the second gate electrode G42 intersect.

The third pull-down transistor PD43 may be formed at the portion where the first active pattern F41 and the seventh gate electrode G47 intersect. The third pull-up transistor PU43 may be formed at the portion where the fourth active pattern F44 and the seventh gate electrode G47 intersect. The third pass transistor PG43 may be formed at the portion where the first active pattern F41 and the fifth gate electrode G45 intersect. The fourth pull-down transistor PD44 may be formed at the portion where the third active pattern F43 and the sixth gate electrode G46 intersect. The fourth pull-up transistor PU44 may be formed at the portion where the fourth active pattern F44 and the sixth gate electrode G46 intersect. The fourth pass transistor PG44 may be formed at the portion where the third active pattern F43 and the eighth gate electrode G48 intersect.

Each of the first to fourth pull-down transistors PD41 to PD44 may be an NMOS transistor, and each of the first to fourth pull-up transistors PU41 to PU44 may be a PMOS transistor. Each of the first to fourth pull-up transistors PU41 to PU44 may be aligned in the first horizontal direction DR1.

The first lower source/drain contact BCA41 may be disposed on the boundary line of the first cell region R41 adjacent to the first gate electrode G41 in the first horizontal direction DR1. The first lower source/drain contact BCA41 may penetrate the substrate 100 and the first active pattern F41 in the vertical direction DR3 to extend into the first source/drain region. The first lower source/drain contact BCA41 may be connected to the first buried rail VSS41 that is the first ground rail. The second lower source/drain contact BCA42 may be disposed between the first gate electrode G41 and the fourth gate electrode G44. The second lower source/drain contact BCA42 may penetrate the substrate 100 and the second active pattern F42 in the vertical direction DR3 to extend into the second source/drain region SD42. The second lower source/drain contact BCA42 may be connected to the second buried rail VDD4 that is the power rail.

The third lower source/drain contact BCA43 may be disposed between the fourth gate electrode G44 and the sixth gate electrode G46. The third lower source/drain contact BCA43 may be disposed on the boundary line between the first cell region R41 and the second cell region R42. For example, the third lower source/drain contact BCA43 may be formed on the same boundary line as the second active cut FC42. The third lower source/drain contact BCA43 may penetrate the substrate 100 and the third active pattern F43 in the vertical direction DR3 to extend into the third source/drain region. The third lower source/drain contact BCA43 may be connected to the third buried rail VSS42 that is the second ground rail. The fourth lower source/drain contact BCA44 may be disposed between the sixth gate electrode G46 and the seventh gate electrode G47. The fourth lower source/drain contact BCA44 may penetrate the substrate 100 and the fourth active pattern F44 in the vertical direction DR3 to extend into the fourth source/drain region SD44. The fourth lower source/drain contact BCA44 may be connected to the second buried rail VDD4 that is the power rail.

The fifth lower source/drain contact BCA45 may be disposed on the boundary line of the second cell region R42 adjacent to the seventh gate electrode G47 in the first horizontal direction DR1. The fifth lower source/drain contact BCA45 may penetrate the substrate 100 and the first active pattern F41 in the vertical direction DR3 to extend into the first source/drain region. The fifth lower source/drain contact BCA45 may be connected to the first buried rail VSS41 that is the first ground rail. The first to eighth gate contacts CB41 to CB48 may penetrate the capping pattern 123 in the vertical direction DR3 to be connected to the first to eighth gate electrodes G41 to G48, respectively.

The first upper source/drain contact UCA41 may be disposed between the first active cut FC41 and the first gate electrode G41. The first upper source/drain contact UCA41 may overlap the second active pattern F42. The first upper source/drain contact UCA41 may penetrate the first upper interlayer insulating layer 140 in the vertical direction DR3 to be connected to the second source/drain region SD42. The second upper source/drain contact UCA42 may be disposed on the boundary line of the first cell region R41 adjacent to the second gate electrode G42 in the first horizontal direction DR1. The second upper source/drain contact UCA42 may penetrate the first upper interlayer insulating layer 140 in the vertical direction DR3 to be connected to the third source/drain region.

The third upper source/drain contact UCA43 may be disposed between the first gate electrode G41 and the third gate electrode G43. The third upper source/drain contact UCA43 may penetrate the first upper interlayer insulating layer 140 in the vertical direction DR3 to be connected to the first source/drain region. The fourth upper source/drain contact UCA44 may be disposed between the second gate electrode G42 and the fourth gate electrode G44. The fourth upper source/drain contact UCA44 may penetrate the first upper interlayer insulating layer 140 in the vertical direction DR3 to be connected to the third source/drain region.

The fifth upper source/drain contact UCA45 may be disposed on the boundary line between the first cell region R41 and the second cell region R42. The fifth upper source/drain contact UCA45 may be formed on the same boundary line as the third lower source/drain contact BCA43 and the second active cut FC42. The fifth upper source/drain contact UCA45 may penetrate the first upper interlayer insulating layer 140 in the vertical direction DR3 to be connected to the first source/drain region. The sixth upper source/drain contact UCA46 may be disposed between the fourth gate electrode G44 and the second active cut FC42. The sixth upper source/drain contact UCA46 may penetrate the first upper interlayer insulating layer 140 in the vertical direction DR3 to be connected to the second source/drain region SD42. The seventh upper source/drain contact UCA47 may be disposed between the second active cut FC42 and the sixth gate electrode G46. The seventh upper source/drain contact UCA47 may penetrate the first upper interlayer insulating layer 140 in the vertical direction DR3 to be connected to the fourth source/drain region SD44.

The eighth upper source/drain contact UCA48 may be disposed between the fifth gate electrode G45 and the seventh gate electrode G47. The eighth upper source/drain contact UCA48 may penetrate the first upper interlayer insulating layer 140 in the vertical direction DR3 to be connected to the first source/drain region. The ninth upper source/drain contact UCA49 may be disposed between the sixth gate electrode G46 and the eighth gate electrode G48. The ninth upper source/drain contact UCA49 may penetrate the first upper interlayer insulating layer 140 in the vertical direction DR3 to be connected to the third source/drain region.

The tenth upper source/drain contact UCA50 may be disposed between the seventh gate electrode G57 and the third active cut FC53. The tenth upper source/drain contact UCA50 may penetrate the first upper interlayer insulating layer 140 in the vertical direction DR3 to be connected to the fourth source/drain region SD44. The eleventh upper source/drain contact UCA51 may be disposed on the boundary line of the second cell region R42 adjacent to the eighth gate electrode G48 in the first horizontal direction DRL. The eleventh upper source/drain contact UCA51 may penetrate the first upper interlayer insulating layer 140 in the vertical direction DR3 to be connected to the third source/drain region.

For example, the width in the first horizontal direction DR1 of each of the first upper source/drain contact UCA41, the sixth upper source/drain contact UCA46, the seventh upper source/drain contact UCA47, and the tenth upper source/drain contact UCA50 may be smaller than the width in the first horizontal direction DR1 of each of the second upper source/drain contact UCA42, the third upper source/drain contact UCA43, the fourth upper source/drain contact UCA44, the fifth upper source/drain contact UCA45, the eighth upper source/drain contact UCA48, the ninth upper source/drain contact UCA49, and the eleventh upper source/drain contact UCA51.

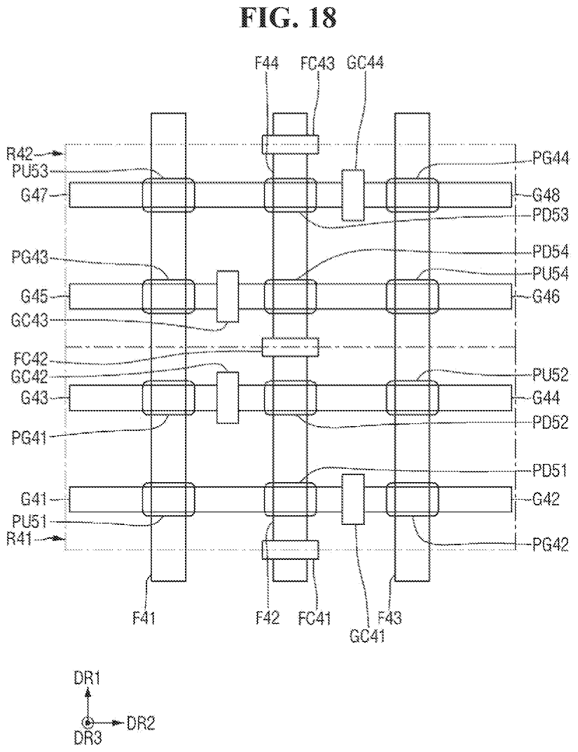

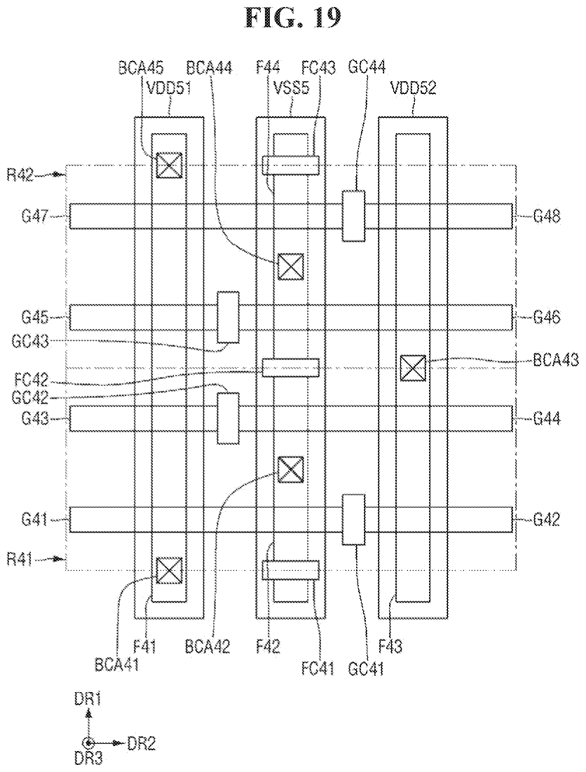

Hereinafter, a semiconductor device according to some other embodiments of the present disclosure will be described with reference to FIGS. 18 and 19. Differences from the semiconductor device shown in FIGS. 13 to 17 will be mainly described.

FIGS. 18 and 19 are layout views illustrating a semiconductor device according to some other embodiments of the present disclosure.

Referring to FIGS. 18 and 19, in a semiconductor device according to some other embodiments of the present disclosure, a first buried rail VDD51 may be a first power rail, a second buried rail VSS5 may be a ground rail, and a third buried rail VDD52 may be a second power rail.

For example, the first buried rail VDD51 that is the first power rail may overlap the first active pattern F41 in the vertical direction DR3. The second buried rail VSS5 that is the ground rail may overlap each of the second active pattern F42 and the fourth active pattern F44 in the vertical direction DR3. The third buried rail VDD52 that is the second power rail may overlap the third active pattern F43 in the vertical direction DR3.

A first pull-up transistor PU51 may be formed at the portion where the first active pattern F41 and the first gate electrode G41 intersect. A first pull-down transistor PD51 may be formed at the portion where the second active pattern F42 and the first gate electrode G41 intersect. A second pull-up transistor PU52 may be formed at the portion where the third active pattern F43 and the fourth gate electrode G44 intersect. A second pull-down transistor PD52 may be formed at the portion where the second active pattern F42 and the fourth gate electrode G44 intersect.

A third pull-up transistor PU53 may be formed at the portion where the first active pattern F41 and the seventh gate electrode G47 intersect. A third pull-down transistor PD53 may be formed at the portion where the fourth active pattern F44 and the seventh gate electrode G47 intersect. A fourth pull-up transistor PU54 may be formed at the portion where the third active pattern F43 and the sixth gate electrode G46 intersect. A fourth pull-down transistor PD54 may be formed at the portion where the fourth active pattern F44 and the sixth gate electrode G46 intersect.

Each of the first to fourth pull-down transistors PD51 to PD54 may be an NMOS transistor, and each of the first to fourth pull-up transistors PU51 to PU54 may be a PMOS transistor. Each of the first to fourth pull-down transistors PD51 to PD54 may be aligned in the first horizontal direction DR1.

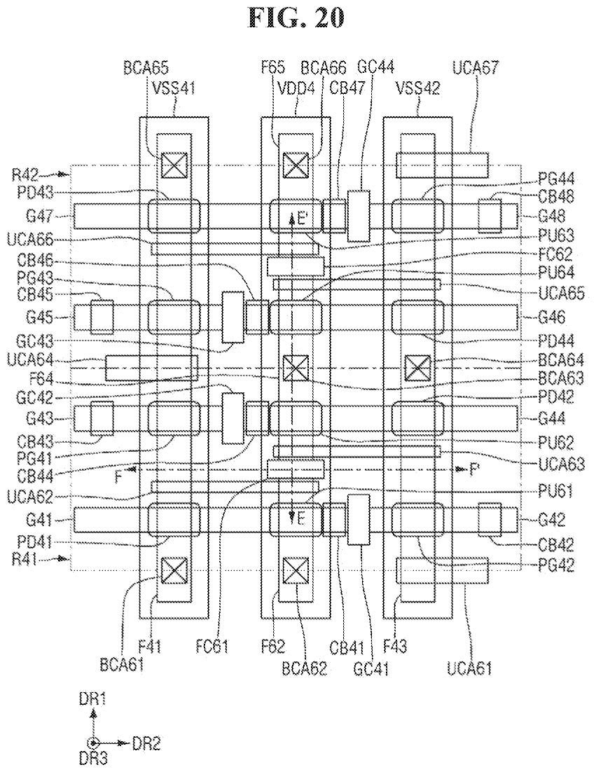

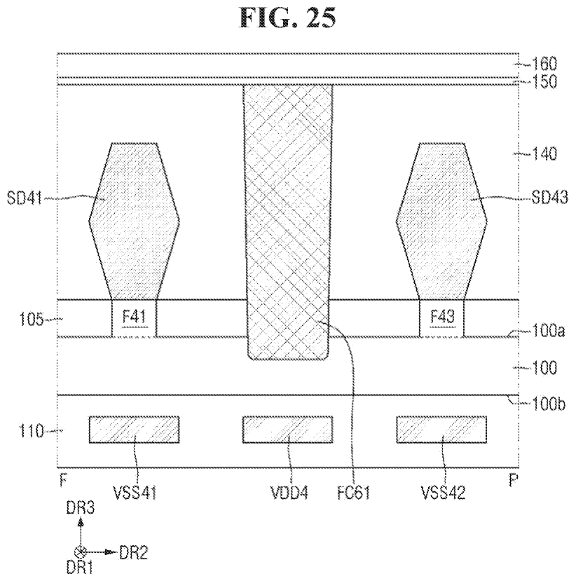

Hereinafter, a semiconductor device according to some other embodiments of the present disclosure will be described with reference to FIGS. 20 and 25. Differences from the semiconductor device shown in FIGS. 13 to 17 will be mainly described.

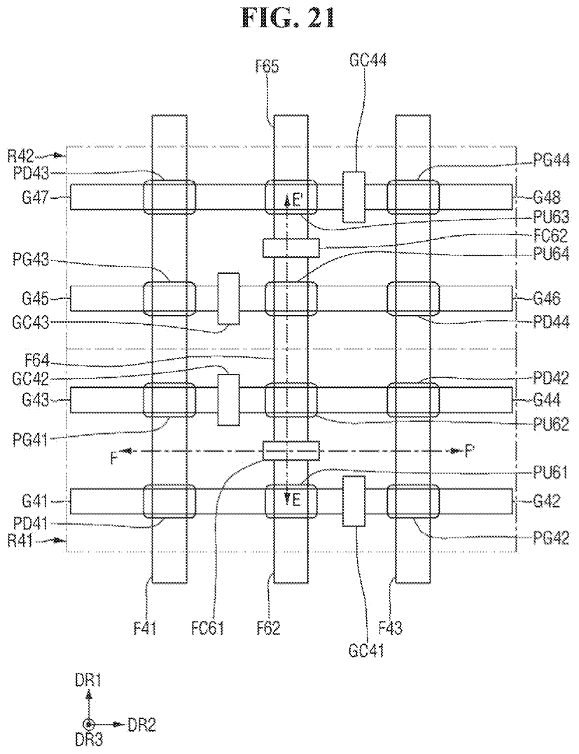

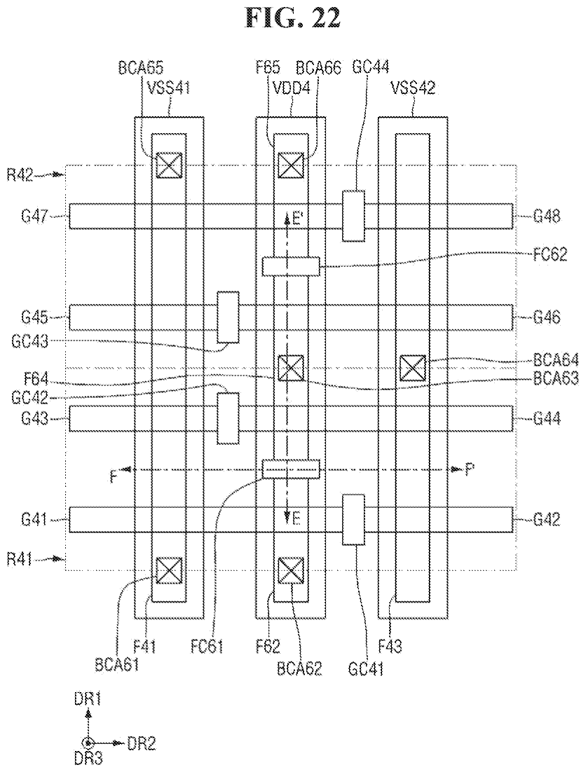

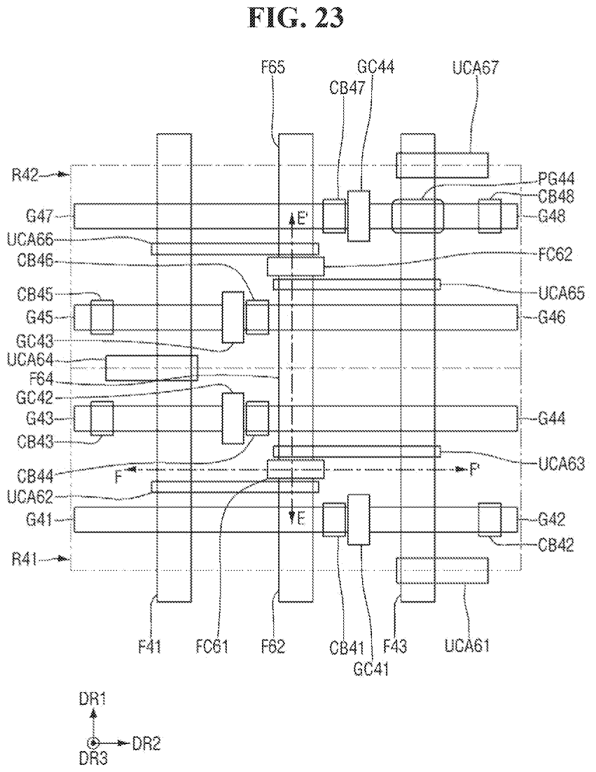

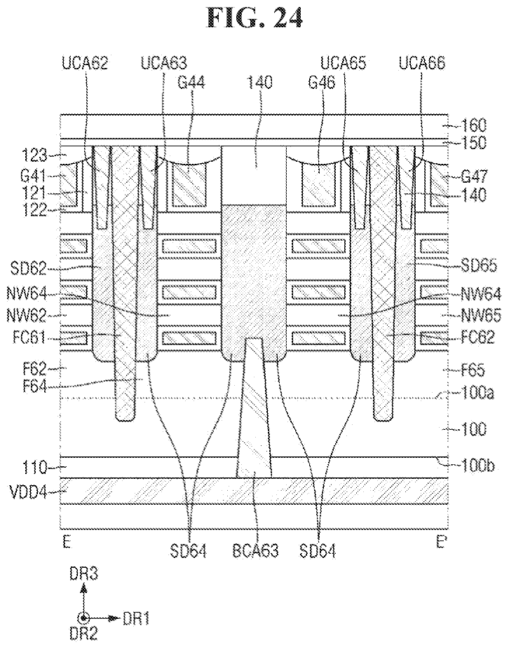

FIG. 20 is a layout diagram illustrating a semiconductor device according to still other embodiments of the present disclosure. FIG. 21 is a layout diagram illustrating an arrangement of a plurality of transistors in FIG. 20. FIG. 22 is a layout diagram illustrating a connection relationship between buried rails in FIG. 20. FIG. 23 is a layout diagram illustrating a connection relationship between a gate contact and an upper source/drain contact in FIG. 20. FIG. 24 is a cross-sectional view taken along line E-E′ in each of FIGS. 20 to 23. FIG. 25 is a cross-sectional view taken along line F-F′ in each of FIGS. 20 to 23.

Referring to FIGS. 20 to 25, in a semiconductor device according to some other embodiments of the present disclosure, a first active cut FC61 may be disposed in the first cell region R41, and a second active cut FC62 may be disposed in the second cell region R42.

The first active pattern F41 may continuously extend in the first horizontal direction DR1 on the first cell region R41 and the second cell region R42. A second active pattern F62 may extend in the first horizontal direction DR1 on the first cell region R41. The second active pattern F62 may be spaced apart from the first active pattern F41 in the second horizontal direction DR2. The third active pattern F43 may continuously extend in the first horizontal direction DR1 on the first cell region R41 and the second cell region R42. The third active pattern F43 may be spaced apart from the second active pattern F42 in the second horizontal direction DR2.

A fourth active pattern F64 may extend in the first horizontal direction DR1 on the first cell region R41 and the second cell region R42. The fourth active pattern F64 may be disposed between the first active pattern F41 and the third active pattern F43. The fourth active pattern F64 may be spaced apart from the second active pattern F62 in the first horizontal direction DR1. A fifth active pattern F65 may extend in the first horizontal direction DR1 on the second cell region R42. The fifth active pattern F65 may be disposed between the first active pattern F41 and the third active pattern F43. The fifth active pattern F65 may be spaced apart from the fourth active pattern F64 in the first horizontal direction DR1.

Each of the second active pattern F62, the fourth active pattern F64, and the fifth active pattern F65 may be aligned in the first horizontal direction DR1. For example, each of the second active pattern F62, the fourth active pattern F64, and the fifth active pattern F65 may overlap the second buried rail VDD4 that is the power rail in the vertical direction DR3.

At the portion where each of the first to fifth active patterns F41, F62, F43, F64, and F65 and each of the first to eighth gate electrodes G41 to G48 intersect, a plurality of nanosheets may be disposed on each of the first to fifth active patterns F41, F62, F43, F64, and F65. For example, a second plurality of nanosheets NW62 may be disposed on the second active pattern F62. The second plurality of nanosheets NW62 may be disposed at the portion where the second active pattern F62 and the first gate electrode G41 intersect. The second plurality of nanosheets NW62 may include a plurality of nanosheets stacked while being spaced apart from each other in the vertical direction DR3 on the second active pattern F62. The second plurality of nanosheets NW62 may be surrounded by the first gate electrode G41.

For example, a fourth plurality of nanosheets NW64 may be disposed on the fourth active pattern F64. The fourth plurality of nanosheets NW64 may be disposed at the portion where the fourth active pattern F64 and the fourth gate electrode G44 intersect. Further, the fourth plurality of nanosheets NW64 may be disposed at the portion where the fourth active pattern F64 and the sixth gate electrode G46 intersect. The fourth plurality of nanosheets NW64 may include a plurality of nanosheets stacked while being spaced apart from each other in the vertical direction DR3 on the fourth active pattern F64. The fourth plurality of nanosheets NW64 may be surrounded by each of the fourth gate electrode G44 and the sixth gate electrode G46.

For example, a fifth plurality of nanosheets NW65 may be disposed on the fifth active pattern F65. The fifth plurality of nanosheets NW65 may be disposed at the portion where the fifth active pattern F65 and the seventh gate electrode G47 intersect. The fifth plurality of nanosheets NW65 may include a plurality of nanosheets stacked while being spaced apart from each other in the vertical direction DR3 on the fifth active pattern F65. The fifth plurality of nanosheets NW65 may be surrounded by the seventh gate electrode G47.

A first source/drain region SD41 may be formed on both sides of each of the first gate electrode G41, the third gate electrode G43, the fifth gate electrode G45, and the seventh gate electrode G47 on the first active pattern F41. The first source/drain region SD41 may be in direct contact with the first active pattern F41. A second source/drain region SD62 may be disposed on both sides of the first gate electrode G41 on the second active pattern F62. A third source/drain region SD43 may be disposed on both sides of each of the second gate electrode G42, the fourth gate electrode G44, the sixth gate electrode G46, and the eighth gate electrode G48 on the third active pattern F43. A fourth source/drain region SD64 may be disposed on both sides of each of the fourth gate electrode G44 and the sixth gate electrode G46 on the fourth active pattern F64. A fifth source/drain region SD65 may be disposed on both sides of the seventh gate electrode G47 on the fifth active pattern F65.

The first active cut FC61 may be disposed in the first cell region R1. The first active cut FC61 may be disposed between the first gate electrode G41 and the fourth gate electrode G44. The first active cut FC61 may separate the second active pattern F62 from the fourth active pattern F64. The first active cut FC61 may be in contact with each of the second active pattern F62 and the fourth active pattern F64.

The first active cut FC61 may separate the source/drain region disposed between the first gate electrode G41 and the fourth gate electrode G44. For example, the second source/drain region SD62 may be disposed between the first gate electrode G41 and the first active cut FC61. Further, the fourth source/drain region SD64 may be disposed between the first active cut FC61 and the fourth gate electrode G44. In other words, the second source/drain region SD62 and the fourth source/drain region SD64 may be separated from each other by the first active cut FC61. The first active cut FC61 may be in contact with each of the second source/drain region SD62 and the fourth source/drain region SD64.

The second active cut FC62 may be disposed in the second cell region R2. The second active cut FC62 may be disposed between the sixth gate electrode G46 and the seventh gate electrode G47. The second active cut FC62 may separate the fourth active pattern F64 from the fifth active pattern F65. The second active cut FC62 may be in contact with each of the fourth active pattern F64 and the fifth active pattern F65.

The second active cut FC62 may separate the source/drain region disposed between the sixth gate electrode G46 and the seventh gate electrode G47. For example, the fourth source/drain region SD64 may be disposed between the sixth gate electrode G46 and the second active cut FC62. Further, the fifth source/drain region SD65 may be disposed between the second active cut FC62 and the seventh gate electrode G47. In other words, the fourth source/drain region SD64 and the fifth source/drain region SD65 may be separated from each other by the second active cut FC62. The second active cut FC62 may be in contact with each of the fourth source/drain region SD64 and the fifth source/drain region SD65.

The first pull-down transistor PD41 may be formed at the portion where the first active pattern F41 and the first gate electrode G41 intersect. The first pull-up transistor PU61 may be formed at the portion where the second active pattern F62 and the first gate electrode G41 intersect. The first pass transistor PG41 may be formed at the portion where the first active pattern F41 and the third gate electrode G43 intersect. The second pull-down transistor PD42 may be formed at the portion where the third active pattern F63 and the fourth gate electrode G44 intersect. The second pull-up transistor PU62 may be formed at the portion where the fourth active pattern F64 and the fourth gate electrode G44 intersect. The second pass transistor PG42 may be formed at the portion where the third active pattern F43 and the second gate electrode G42 intersect.

The third pull-down transistor PD43 may be formed at the portion where the first active pattern F41 and the seventh gate electrode G47 intersect. The third pull-up transistor PU63 may be formed at the portion where the fifth active pattern F65 and the seventh gate electrode G47 intersect. The third pass transistor PG43 may be formed at the portion where the first active pattern F41 and the fifth gate electrode G45 intersect. The fourth pull-down transistor PD44 may be formed at the portion where the third active pattern F43 and the sixth gate electrode G46 intersect. The fourth pull-up transistor PU64 may be formed at the portion where the fourth active pattern F64 and the sixth gate electrode G46 intersect. The fourth pass transistor PG44 may be formed at the portion where the third active pattern F43 and the eighth gate electrode G48 intersect.

Each of the first to fourth pull-down transistors PD41 to PD44 may be an NMOS transistor, and each of the first to fourth pull-up transistors PU61 to PU64 may be a PMOS transistor. Each of the first to fourth pull-up transistors PU61 to PU64 may be aligned in the first horizontal direction DR1.

A first lower source/drain contact BCA61 may be disposed on the boundary line of the first cell region R41 adjacent to the first gate electrode G41 in the first horizontal direction DR1. The first lower source/drain contact BCA61 may penetrate the substrate 100 and the first active pattern F41 in the vertical direction DR3 to extend into the first source/drain region SD41. The first lower source/drain contact BCA61 may be connected to the first buried rail VSS41 that is the first ground rail. A second lower source/drain contact BCA62 may be disposed on the boundary line of the first cell region R41 adjacent to the first gate electrode G41 in the first horizontal direction DR1. The second lower source/drain contact BCA62 may be spaced apart from the first lower source/drain contact BCA61 in the second horizontal direction DR2. The second lower source/drain contact BCA62 may be formed on the same boundary line as the first lower source/drain contact BCA61. The second lower source/drain contact BCA62 may penetrate the substrate 100 and the second active pattern F62 in the vertical direction DR3 to extend into the second source/drain region SD62. The second lower source/drain contact BCA62 may be connected to the second buried rail VDD4 that is the power rail.

A third lower source/drain contact BCA63 may be disposed between the fourth gate electrode G44 and the sixth gate electrode G46. The third lower source/drain contact BCA63 may be disposed on the boundary line between the first cell region R41 and the second cell region R42. The third lower source/drain contact BCA63 may penetrate the substrate 100 and the fourth active pattern F64 in the vertical direction DR3 to extend into the fourth source/drain region SD64. The third lower source/drain contact BCA63 may be connected to the second buried rail VDD4 that is the power rail. A fourth lower source/drain contact BCA64 may be disposed between the fourth gate electrode G44 and the sixth gate electrode G46. The fourth lower source/drain contact BCA64 may be disposed on the boundary line between the first cell region R41 and the second cell region R42. The fourth lower source/drain contact BCA64 may be spaced apart from the third lower source/drain contact BCA63 in the second horizontal direction DR2. The fourth lower source/drain contact BCA64 may be formed on the same boundary line as the third lower source/drain contact BCA63. The fourth lower source/drain contact BCA64 may penetrate the substrate 100 and the third active pattern F43 in the vertical direction DR3 to extend into the third lower source/drain contact BCA63. The fourth lower source/drain contact BCA64 may be connected to the third buried rail VSS42 that is the second ground rail.

A fifth lower source/drain contact BCA65 may be disposed on the boundary line of the second cell region R42 adjacent to the seventh gate electrode G47 in the first horizontal direction DR1. The fifth lower source/drain contact BCA65 may penetrate the substrate 100 and the first active pattern F41 in the vertical direction DR3 to extend into the first source/drain region SD41. The fifth lower source/drain contact BCA65 may be connected to the first buried rail VSS41 that is the first ground rail. A sixth lower source/drain contact BCA66 may be disposed on the boundary line of the second cell region R42 adjacent to the seventh gate electrode G47 in the first horizontal direction DR1. The sixth lower source/drain contact BCA66 may be spaced apart from the fifth lower source/drain contact BCA65 in the second horizontal direction DR2. The sixth lower source/drain contact BCA66 may be formed on the same boundary line as the fifth lower source/drain contact BCA65. The sixth lower source/drain contact BCA66 may penetrate the substrate 100 and the fifth active pattern F65 in the vertical direction DR3 to extend into the fifth source/drain region SD65. The sixth lower source/drain contact BCA66 may be connected to the second buried rail VDD4 that is the power rail.

A first upper source/drain contact UCA61 may be disposed on the boundary line of the first cell region R41 adjacent to the second gate electrode G42 in the first horizontal direction DR1. The first upper source/drain contact UCA61 may penetrate the first upper interlayer insulating layer 140 in the vertical direction DR3 to be connected to the third source/drain region SD43. A second upper source/drain contact UCA62 may be disposed between the first gate electrode G41 and the first active cut FC61. The second upper source/drain contact UCA62 may be adjacent to the first active cut FC61 in an area overlapping the second buried rail VDD4. The second upper source/drain contact UCA62 may overlap each of the first active pattern F41 and the second active pattern F62 in the vertical direction DR3. The second upper source/drain contact UCA62 may penetrate the first upper interlayer insulating layer 140 in the vertical direction DR3 to be connected to each of the first source/drain region SD41 and the second source/drain region SD62.

A third upper source/drain contact UCA63 may be disposed between the first active cut FC61 and the fourth gate electrode G44. The first active cut FC61 may be disposed between the third upper source/drain contact UCA63 and the second upper source/drain contact UCA62 in an area overlapping the second buried rail VDD4. The third upper source/drain contact UCA63 may overlap each of the fourth active pattern F64 and the third active pattern F43 in the vertical direction DR3. The third upper source/drain contact UCA63 may penetrate the first upper interlayer insulating layer 140 in the vertical direction DR3 to be connected to each of the fourth source/drain region SD64 and the third source/drain region SD43. A fourth upper source/drain contact UCA64 may be disposed between the third gate electrode G43 and the fifth gate electrode G45. The fourth upper source/drain contact UCA64 may be disposed on the boundary line between the first cell region R41 and the second cell region R42. The fourth upper source/drain contact UCA64 may penetrate the first upper interlayer insulating layer 140 in the vertical direction DR3 to be connected to the first source/drain region SD41.

A fifth upper source/drain contact UCA65 may be disposed between the sixth gate electrode G46 and the second active cut FC62. The fifth upper source/drain contact UCA65 may overlap each of the fourth active pattern F64 and the third active pattern F43 in the vertical direction DR3. The fifth upper source/drain contact UCA65 may penetrate the first upper interlayer insulating layer 140 in the vertical direction DR3 to be connected to each of the fourth source/drain region SD64 and the third source/drain region SD43. A sixth upper source/drain contact UCA66 may be disposed between the second active cut FC62 and the seventh gate electrode G47. The second active but FC62 may be disposed between the sixth upper source/drain contact UCA66 and the fifth upper source/drain contact UCA65. The sixth upper source/drain contact UCA66 may overlap each of the first active pattern F41 and the fifth active pattern F65 in the vertical direction DR3. The sixth upper source/drain contact UCA66 may penetrate the first upper interlayer insulating layer 140 in the vertical direction DR3 to be connected to each of the first source/drain region SD41 and the fifth source/drain region SD65. A seventh upper source/drain contact UCA67 may be disposed on the boundary line of the second cell region R42 adjacent to the eighth gate electrode G48 in the first horizontal direction DR1. The seventh upper source/drain contact UCA67 may penetrate the first upper interlayer insulating layer 140 in the vertical direction DR3 to be connected to the third source/drain region SD43.

For example, the width in the first horizontal direction DR1 of each of the second upper source/drain contact UCA62, the third upper source/drain contact UCA63, the fifth upper source/drain contact UCA65, and the sixth upper source/drain contact UCA66 may be smaller than the width in the first horizontal direction DR1 of each of the first upper source/drain contact UCA61, the fourth upper source/drain contact UCA64, and the seventh upper source/drain contact UCA67.

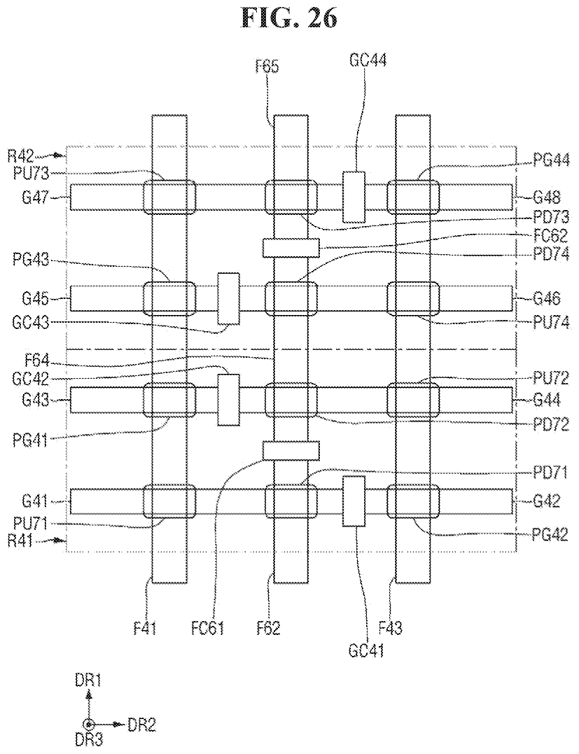

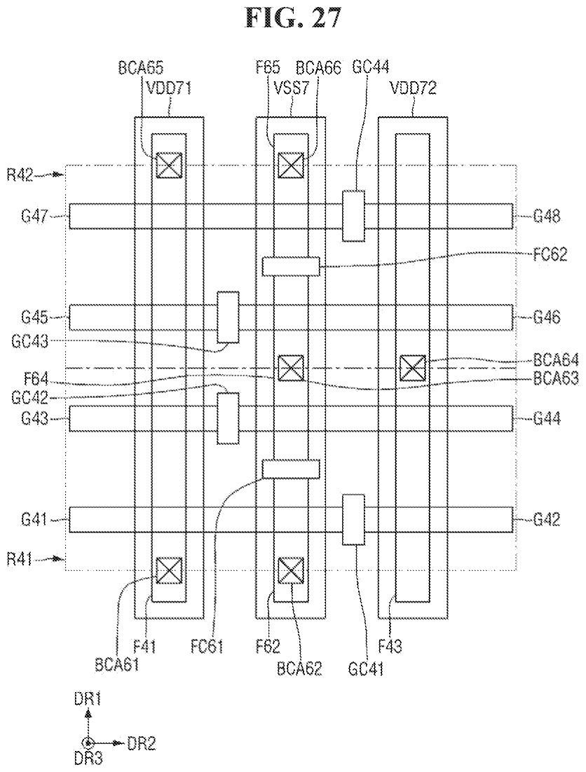

Hereinafter, a semiconductor device according to some other embodiments of the present disclosure will be described with reference to FIGS. 26 and 27. Differences from the semiconductor device shown in FIGS. 20 to 25 will be mainly described.

FIGS. 26 and 27 are layout diagrams illustrating a semiconductor device according to some other embodiments of the present disclosure.

Referring to FIGS. 26 and 27, in a semiconductor device according to some other embodiments of the present disclosure, a first buried rail VDD71 may be a first power rail, a second buried rail VSS7 may be a ground rail, and a third buried rail VDD72 may be a second power rail.

For example, the first buried rail VDD71 that is the first power rail may overlap the first active pattern F41 in the vertical direction DR3. The second buried rail VSS7 that is the ground rail may overlap each of the second active pattern F62, the fourth active pattern F64, and the fifth active pattern F65 in the vertical direction DR3. The third buried rail VDD72 that is the second power rail may overlap the third active pattern F43 in the vertical direction DR3. A first pull-up transistor PU71 may be formed at the portion where the first active pattern F41 and the first gate electrode G41 intersect. A first pull-down transistor PD71 may be formed at the portion where the second active pattern F62 and the first gate electrode G41 intersect. A second pull-up transistor PU72 may be formed at the portion where the third active pattern F43 and the fourth gate electrode G44 intersect. A second pull-down transistor PD72 may be formed at the portion where the fourth active pattern F64 and the fourth gate electrode G44 intersect.

A third pull-up transistor PU73 may be formed at the portion where the first active pattern F41 and the seventh gate electrode G47 intersect. A third pull-down transistor PD73 may be formed at the portion where the fifth active pattern F65 and the seventh gate electrode G47 intersect. A fourth pull-up transistor PU74 may be formed at the portion where the third active pattern F43 and the sixth gate electrode G46 intersect. A fourth pull-down transistor PD74 may be formed at the portion where the fourth active pattern F64 and the sixth gate electrode G46 intersect.

Each of the first to fourth pull-down transistors PD71 to PD74 may be an NMOS transistor, and each of the first to fourth pull-up transistors PU71 to PU74 may be a PMOS transistor. Each of the first to fourth pull-down transistors PD71 to PD74 may be aligned in the first horizontal direction DR1.

In concluding the detailed description, those skilled in the art will appreciate that many variations and modifications can be made to the embodiments disclosed herein without substantially departing from the principles of the present disclosure. Therefore, the disclosed embodiments are used in a generic and descriptive sense and not for purposes of limitation.

What is claimed is:

1. A semiconductor device, comprising:
a first cell region and a second cell region adjacent to the first cell region in a first horizontal direction;
a substrate comprising a first surface and a second surface opposite to the first surface;
first, second and third active patterns extending in the first horizontal direction on the first surface of the substrate in the first cell region, the first, second and third active patterns are sequentially spaced apart from each other in a second horizontal direction different from the first horizontal direction;
a fourth active pattern extending in the first horizontal direction on the first surface of the substrate in the second cell region, the fourth active pattern is aligned with the second active pattern in the first horizontal direction;
a first active cut separating the second active pattern and the fourth active pattern, the first active cut is in contact with each of the second active pattern and the fourth active pattern;
a first source/drain region disposed on the second active pattern;
a first buried rail extending in the first horizontal direction on the second surface of the substrate, the first buried rail overlaps each of the second and fourth active patterns in a vertical direction; and
a first lower source/drain contact penetrating the substrate and the second active pattern in the vertical direction, the first lower source/drain contact electrically connects the first source/drain region to the first buried rail.

2. The semiconductor device of claim 1, further comprising:
a first gate electrode extending in the second horizontal direction on the first active pattern of the first cell region;
a second gate electrode extending in the second horizontal direction on the first active pattern of the first cell region, the second gate electrode is spaced apart from the first gate electrode in the first horizontal direction; and
a third gate electrode extending in the second horizontal direction on the first active pattern of the second cell region, the third gate electrode is spaced apart from the second gate electrode in the first horizontal direction,
wherein the first active pattern continuously extends in the first horizontal direction in each of the first and second cell regions, and
wherein a pitch in the first horizontal direction between a center of the second gate electrode and a center of the third gate electrode is equal to or greater than a pitch in the first horizontal direction between a center of the first gate electrode and a center of the second gate electrode.

3. The semiconductor device of claim 1, further comprising:
a second source/drain region disposed on the first active pattern;
a third source/drain region disposed on the third active pattern;
a second buried rail extending in the first horizontal direction on the second surface of the substrate, the second buried rail overlaps the first active pattern in the vertical direction;
a third buried rail extending in the first horizontal direction on the second surface of the substrate, the third buried rail overlaps the third active pattern in the vertical direction;
a second lower source/drain contact penetrating the substrate and the first active pattern in the vertical direction, the second lower source/drain contact electrically connects the second source/drain region to the second buried rail; and
a third lower source/drain contact penetrating the substrate and the third active pattern in the vertical direction, the third lower source/drain contact electrically connects the third source/drain region to the third buried rail.

4. The semiconductor device of claim 3, wherein the first buried rail is a power rail, and each of the second buried rail and the third buried rail is a ground rail.

5. The semiconductor device of claim 3, wherein the first buried rail is a ground rail, and each of the second buried rail and the third buried rail is a power rail.

6. The semiconductor device of claim 1, further comprising:
a first gate electrode extending in the second horizontal direction on the second active pattern;
a second gate electrode extending in the second horizontal direction on the second active pattern, the second gate electrode is spaced apart from the first gate electrode in the first horizontal direction;
a third gate electrode extending in the second horizontal direction on the fourth active pattern, the third gate electrode is spaced apart from the second gate electrode in the first horizontal direction;
a fourth gate electrode extending in the second horizontal direction on the fourth active pattern, the fourth gate electrode is spaced apart from the third gate electrode in the first horizontal direction;
a first pull-up transistor formed where the second active pattern and the first gate electrode intersect;
a second pull-up transistor formed where the second active pattern and the second gate electrode intersect;
a third pull-up transistor formed where the fourth active pattern and the third gate electrode intersect; and
a fourth pull-up transistor formed where the fourth active pattern and the fourth gate electrode intersect,
wherein each of the first to fourth pull-up transistors is aligned in the first horizontal direction.

7. The semiconductor device of claim 1, further comprising:
a fifth active pattern extending in the first horizontal direction on the first surface of the substrate in the second cell region, the fifth active pattern is spaced apart from the first active pattern in the first horizontal direction; and
a sixth active pattern extending in the first horizontal direction on the first surface of the substrate in the second cell region, the sixth active pattern is spaced apart from the third active pattern in the first horizontal direction,
wherein the first active cut extends in the second horizontal direction, the first active cut separates the first active pattern from the fifth active pattern, the first active cut separates the third active pattern from the sixth active pattern, the first active cut is in contact with the first active pattern, the third active pattern, the fifth active pattern, and the sixth active pattern.

8. The semiconductor device of claim 7, further comprising:
a plurality of dummy nanosheets stacked on the second and fourth active patterns and spaced apart from each other in the vertical direction, the plurality of dummy nanosheets are disposed on a sidewall of the first active cut in the first horizontal direction;
a dummy gate electrode disposed on the sidewall of the first active cut in the first horizontal direction between the plurality of dummy nanosheets; and
a dummy gate spacer extending in the second horizontal direction along the sidewall of the first active cut in the first horizontal direction on the plurality of dummy nanosheets, the dummy gate spacer is in contact with the sidewall of the first active cut in the first horizontal direction.

9. The semiconductor device of claim 1, wherein each of the first and third active patterns continuously extends in the first horizontal direction in each of the first and second cell regions, and
the fourth active pattern is disposed between the first active pattern and the third active pattern in the second cell region.

10. The semiconductor device of claim 1, wherein the first active cut is disposed on a boundary between the first cell region and the second cell region.

11. The semiconductor device of claim 1, further comprising:
a fifth active pattern extending in the first horizontal direction on the first surface of the substrate in the second cell region, the fifth active pattern is spaced apart from the fourth active pattern in the first horizontal direction; and
a second active cut separating the fourth active pattern from the fifth active pattern, the second active cut is in contact with each of the fourth active pattern and the fifth active pattern,
wherein the fourth active pattern extends in the first horizontal direction in each of the first and second cell regions,
wherein the first active cut is disposed in the first cell region, and
wherein the second active cut is disposed in the second cell region.

12. The semiconductor device of claim 11, further comprising:
a first gate electrode extending in the second horizontal direction on the second active pattern;
a second gate electrode extending in the second horizontal direction on the fourth active pattern, the second gate electrode is spaced apart from the first gate electrode in the first horizontal direction;
a third gate electrode extending in the second horizontal direction on the fourth active pattern, the third gate electrode is spaced apart from the second gate electrode in the first horizontal direction;
a fourth gate electrode extending in the second horizontal direction on the fifth active pattern, the fourth gate electrode is spaced apart from the third gate electrode in the first horizontal direction;
a first pull-up transistor formed where the second active pattern and the first gate electrode intersect;
a second pull-up transistor formed where the fourth active pattern and the second gate electrode intersect;
a third pull-up transistor formed where the fourth active pattern and the third gate electrode intersect; and
a fourth pull-up transistor formed where the fifth active pattern and the fourth gate electrode intersect,
wherein each of the first to fourth pull-up transistors is aligned in the first horizontal direction.

13. A semiconductor device, comprising:
a first cell region and a second cell region adjacent to the first cell region in a first horizontal direction;
a substrate comprising a first surface and a second surface opposite to the first surface;
first, second and third active patterns extending in the first horizontal direction on the first surface of the substrate in the first cell region, the first, second and third active patterns are sequentially spaced apart from each other in a second horizontal direction different from the first horizontal direction;
a fourth active pattern extending in the first horizontal direction on the first surface of the substrate in the second cell region, the fourth active pattern is aligned with the second active pattern in the first horizontal direction;
an active cut separating the second active pattern from the fourth active pattern, the active cut is in contact with each of the second active pattern and the fourth active pattern;
a first source/drain region disposed on the first active pattern;
a second source/drain region disposed on the second active pattern;
a third source/drain region disposed on the third active pattern;
a first buried rail extending in the first horizontal direction on the second surface of the substrate, the first buried rail overlaps the first active pattern in a vertical direction;
a second buried rail extending in the first horizontal direction on the second surface of the substrate, the second buried rail overlaps the second and fourth active patterns in the vertical direction;
a third buried rail extending in the first horizontal direction on the second surface of the substrate, the third buried rail overlaps the third active pattern in the vertical direction;
a first lower source/drain contact penetrating the substrate and the first active pattern in the vertical direction, the first lower source/drain contact electrically connects the first source/drain region to the first buried rail;
a second lower source/drain contact penetrating the substrate and the second active pattern in the vertical direction, the second lower source/drain contact electrically connects the second source/drain region to the second buried rail; and
a third lower source/drain contact penetrating the substrate and the third active pattern in the vertical direction, the third lower source/drain contact electrically connects the third source/drain region to the third buried rail.

14. The semiconductor device of claim 13, further comprising:
a gate electrode extending in the second horizontal direction on the second active pattern;
an interlayer insulating layer covering the second source/drain region; and
an upper source/drain contact penetrating the interlayer insulating layer in the vertical direction, the upper source/drain contact is connected to the second source/drain region on a first side of the gate electrode,
wherein the second lower source/drain contact is connected to the second source/drain region on a second side of the gate electrode opposite to the first side of the gate electrode in the first horizontal direction.

15. The semiconductor device of claim 13, further comprising:
a first gate electrode extending in the second horizontal direction on the second active pattern;
a second gate electrode extending in the second horizontal direction on the second active pattern, the second gate electrode is spaced apart from the first gate electrode in the first horizontal direction;
a third gate electrode extending in the second horizontal direction on the fourth active pattern, the third gate electrode is spaced apart from the second gate electrode in the first horizontal direction;
a fourth gate electrode extending in the second horizontal direction on the fourth active pattern, the fourth gate electrode is spaced apart from the third gate electrode in the first horizontal direction;
a first pull-down transistor formed where the second active pattern and the first gate electrode intersect;
a second pull-down transistor formed where the second active pattern and the second gate electrode intersect;
a third pull-down transistor formed where the fourth active pattern and the third gate electrode intersect; and
a fourth pull-down transistor formed where the fourth active pattern and the fourth gate electrode intersect,
wherein each of the first to fourth pull-down transistors is aligned in the first horizontal direction.

16. The semiconductor device of claim 13, wherein at least a part of a sidewall of the active cut is in contact with the second source/drain region.

17. A semiconductor device, comprising:
a first cell region and a second cell region adjacent to the first cell region in a first horizontal direction;
a substrate comprising a first surface and a second surface opposite to the first surface;
first, second and third active patterns extending in the first horizontal direction on the first surface of the substrate in the first cell region, the first, second and third active patterns are sequentially spaced apart from each other in a second horizontal direction different from the first horizontal direction;
a fourth active pattern extending in the first horizontal direction on the first surface of the substrate in the second cell region, the fourth active pattern is aligned with the second active pattern in the first horizontal direction;
a first gate electrode extending in the second horizontal direction on the second active pattern;
a second gate electrode extending in the second horizontal direction on the second active pattern, the second gate electrode is spaced apart from the first gate electrode in the first horizontal direction;
a third gate electrode extending in the second horizontal direction on the fourth active pattern, the third gate electrode is spaced apart from the second gate electrode in the first horizontal direction;
a fourth gate electrode extending in the second horizontal direction on the fourth active pattern, the fourth gate electrode is spaced apart from the third gate electrode in the first horizontal direction;
a first pull-up transistor formed where the second active pattern and the first gate electrode intersect;
a second pull-up transistor formed where the second active pattern and the second gate electrode intersect;
a third pull-up transistor formed where the fourth active pattern and the third gate electrode intersect; and
a fourth pull-up transistor formed where the fourth active pattern and the fourth gate electrode intersect,
wherein each of the first to fourth pull-up transistors is aligned in the first horizontal direction.

18. The semiconductor device of claim 17, further comprising:
a source/drain region disposed on both sides of the second gate electrode on the second active pattern;
a buried rail extending in the first horizontal direction on the second surface of the substrate, the buried rail overlaps the second and fourth active patterns in a vertical direction; and
a lower source/drain contact penetrating the substrate and the second active pattern in the vertical direction, the lower source/drain contact electrically connects the source/drain region to the buried rail.

19. The semiconductor device of claim 17, further comprising:
a fifth active pattern extending in the first horizontal direction on the first surface of the substrate in the second cell region, the fifth active pattern is spaced apart from the first active pattern in the first horizontal direction;
a sixth active pattern extending in the first horizontal direction on the first surface of the substrate in the second cell region, the sixth active pattern is spaced apart from the third active pattern in the first horizontal direction; and
an active cut extending in the second horizontal direction on a boundary between the first cell region and the second cell region, the active cut separates the first active pattern from the fifth active pattern, the active cut separates the second active pattern from the fourth active pattern, the active cut separates the third active pattern from the sixth active pattern, the active cut is in contact with the first to sixth active patterns.

20. The semiconductor device of claim 17, further comprising:
an active cut separating the second active pattern from the fourth active pattern, the active cut is in contact with the second active pattern and the fourth active pattern,
wherein each of the first and third active patterns continuously extends in the first horizontal direction in each of the first and second cell regions, and
wherein the fourth active pattern is disposed between the first active pattern and the third active pattern in the second cell region.
